(19) United States
(12) Patent Application Publication
(10) Pub. No.: US 2008/0160452 A1
(43) Pub. Date: Jul. 3, 2008

(54) Developer for light sensitive planographic printing plate material and manufacturing process of planographic printing plate employing the same

(75) Inventor: Rieko Takahashi, Tokyo (JP)

Correspondence Address: FRISHAUF, HOLTZ, GOODMAN & CHICK, PC, 220 Fifth Avenue, 16TH Floor, NEW YORK, NY, 10001-7708, US

(73) Assignee: KONICA MINOLTA MEDICAL & GRAPHIC, INC., Tokyo (JP)

(21) Appl. No.: 12/004,221

(22) Filed: Dec. 20, 2007

(30) Foreign Application Priority Data
Dec. 28, 2006 (JP) JP2006-353785

(51) Int. Cl. G03F 7/12; G03F 7/30

(52) U.S. Cl. 430/309; 430/331

(57) ABSTRACT

Disclosed are a developer for an imagewise exposed light sensitive planographic printing plate material and a process of manufacturing a planographic printing plate employing the developer, wherein the developer is an aqueous solution with a pH at 25° C. of from 3.0 to 9.0 containing a compound represented by formula (1),

R¹-Z-(R²—O)ₙ—H Formula (1)

This application is based on Japanese Patent Application No. 2006-353785, filed on Dec. 28, 2006 in Japanese Patent Office, the entire content of which is hereby incorporated by reference.

### FIELD OF THE INVENTION

The present invention relates to a developer for a light sensitive planographic printing plate material and a manufacturing process of a planographic printing plate employing the same, and particularly to a developer with a low pH and with high safety for a light sensitive planographic printing plate material and a manufacturing process of a planographic printing plate employing the same.

### BACKGROUND OF THE INVENTION

A planographic printing plate material is known, which comprises a hydrophilic support and provided thereon, a light sensitive layer and a protective layer in this order. In order to prepare a printing plate with high resolution image rapidly or apply a filmless plate-making, there has been broadly employed a method for preparing a planographic printing plate, in which digital exposure based on image data is carried out using a laser, followed by development. For instance, there is known a plate-making system in which a photosensitive material is directly subjected to scanning exposure, employing a light source modulated based on output signals from an electronic plate-making system or an image processing system or on image signals transferred through a communication line, whereby a printing plate is obtained.

For example, high sensitivity for shortening recording time is desired for printing plate materials for use in CTP (computer-to-plate) to record digital data by laser. High printing durability is also desired in various printing fields including newspaper printing and commercial printing such as advertising prints.

As is generally known, a photopolymerizable light sensitive layer contains an acryl monomer, an alkali-soluble resin, a photopolymerization initiator, and optionally a sensitizing dye to suit the wavelength in laser writing-in. It is also known to provide a protective layer to prevent polymerization inhibition due to oxygen.

Visible light sources of longer wavelengths, such as Ar laser (488 nm) and FD-YAG laser (532 nm) are employable as a light source to expose a photopolymerization type planographic printing plate material used for plate-making. Recently, a continuous-wave laser in the wavelength region of 350 to 450 nm, using InGaN type or ZnS type materials has now entered the stage of practical use. A scanning exposure system using such a light source of a short wavelength has advantages that a semiconductor laser can be manufactured at a relatively low cost in terms of structure and an economical system with a sufficient output can be realized. Such a light source may be usable for a planographic printing plate material which are sensitive to the shorter wavelength region and workable under a lighter safe light, compared to a conventional system using a FD-YAG laser or an Ar laser.

A photopolymerization type planographic printing plate material is usually subjected to imagewise exposure and optionally to a heating treatment, followed by washing to remove a protective layer, development to remove unexposed areas, a washing treatment and a finisher gum treatment to make non-imaged areas hydrophilic, whereby a planographic printing plate is obtained. It is well known that the heat treatment after imagewise exposure promotes polymerization, resulting in enhanced sensitivity and high printing durability.

The light-sensitive layer of a conventional positive working planographic printing plate material uses an ortho-quinonediazide compound in combination with a novolak resin. As a developing solution for such a positive working planographic printing plate material, an aqueous alkaline silicate solution capable of dissolving such a novolak resin is used. A pH of an alkaline solution for dissolving a novolak resin about 13. However, a developing solution with such a high pH is toxic when adhered to skin or mucous membrane, necessitating sufficiently careful treatment. Further, in dots of a small image area (small dots), aluminum under the small dots is dissolved through side-etching, resulting in missing of such small dots during printing, and in lowering printing durability or printed image quality.

As a developer used for removing a light sensitive layer at unexposed portions of a planographic printing plate material, an aqueous alkaline developer with a pH of not less than 12.5 is generally used. However, use of an alkaline developer with a low pH has been required in view of processability, safety and environmental problems.

Disclosed as an alkali silicate-free developer of a low pH (a pH of not more than 12) are a developer of an aqueous potassium hydroxide solution containing an anionic surfactant, as described in Japanese Patent O.P.I. Publication No. 2000-81711 and a developer of an aqueous alkali metal carbonate solution exhibiting a pH of 8.5 to 11.5, as described in Japanese Patent O.P.I. Publication No. 11-65126.

However, a developer with a low pH is basically low in dissolution of a light sensitive layer, and has problems in that in an aged printing plate material, for example, a residual layer or development scum is produced due to under-development.

### SUMMARY OF THE INVENTION

The present invention has-been made in view of the above. An object of the invention is to provide a developer for a light sensitive planographic printing plate material with high sensitivity exhibiting superior developability and minimizing contamination on the printing plate surface caused due to sludge accumulated in a developing bath, and a process of developing a light sensitive planographic printing plate material.

### DETAILED DESCRIPTION OF THE INVENTION

The above object of the present invention can be attained by the following constitution.

1. A developer for an imagewise exposed light sensitive planographic printing plate material, wherein the developer is an aqueous solution with a pH at 25° C. of from 3.0 to 9.0 containing a compound represented by formula (1),

R¹-Z-(R²—O)ₙ—H Formula (1)

wherein R¹ represents a substituted or unsubstituted branched alkyl group having a total carbon atom number of not more than 20; R² represents a substituted or unsubstituted alkylene group having a carbon atom number of from 1 to 10; Z represents —O— or —NH—; n represents an integer of 2 to 100, provided that provided that when n is 2 or more, plural R²S may be the same or different.

2. The developer of item 1 above, wherein the ratio C₂/C₁ of a carbon number C₂ in the side chain of R¹ to a carbon number C₁ in the main chain of R¹ is from 0.05 to 3.0.

3. The developer of item 1 or 2 above, wherein in formula (1), the main chain carbon atom number of R¹ is from 3 to 19, and the side chain carbon atom number of R¹ is from 1 to 9.

4. The developer of any one of items 1 through 3 above, wherein the compound represented by formula (1) has an HLB of from 11 to 15.

5. The developer of any one of items 1 through 4 above, wherein Z in formula (1) is —NH—.

6. The developer of any one of items 1 through 5 above, wherein the developer further contains a water soluble resin.

7. A process of manufacturing a planographic printing plate from a planographic printing plate material comprising a support and provided thereon, a light sensitive layer and an oxygen shielding layer in that order, the light sensitive layer containing a spectral sensitizer, a polymerization initiator, a co-initiator, a polymerizable monomer and a polymeric binder, and the oxygen shielding layer containing polyvinyl alcohol, the process comprising the steps of imagewise exposing the planographic printing plate material; and developing the exposed planographic printing plate material with the developer of any one of claims 1 through 6.

8. The process of item 7 above, wherein the polymerization initiator is a hexaarylbisimidazole compound.

9. The process of item 7 above, wherein the co-initiator is a compound represented by formula (2),

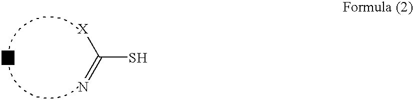

wherein X represents an oxygen atom, a selenium atom or —NR₁—, in which R₁ represents an unsubstituted or substituted alkyl group or an unsubstituted or substituted aryl group; and Y represents an atomic group necessary to form a 5-membered heterocyclic group together with N═C—X.

10. The process of item 7 above, wherein the polymerizable monomer has a hydroxyl group in the molecule.

11. The process of item 7 above, wherein the polymeric binder is a homopolymer or copolymer of N-vinyl pyrrolidone.

12. The process of any one of items 7 through 11 above, between imagewise exposing and developing steps, further comprising the step of heating the exposed light sensitive planographic printing plate material to 80 to 160° C.

13. The process of item 12 above, between heating and developing steps, further comprising the step of removing the oxygen shielding layer and a part of the light sensitive layer by water washing.

14. The process of item 7 above, wherein exposing is carried out employing a laser.

The present invention will be explained below.

The developer of the invention contains a compound represented by formula (1).

### (Compound Represented by Formula (1))

In formula (1), R¹ represents a substituted or unsubstituted branched alkyl group having a total carbon atom number of not more than 20; R² represents a substituted or unsubstituted alkylene group having a carbon atom number of from 1 to 10; Z represents —O— or —NH—; and n represents an integer of 2 to 100, provided that when n is 2 or more, plural R²s may be the same or different.

Examples of the substituent of a substituted branched alkyl group represented by R¹ include a cycloalkyl group (for example, a cyclopentyl group or a cyclohexyl group), an alkenyl group (for example, a vinyl group or a allyl group), an alkinyl group (for example, an ethinyl group or a propargyl group), an aryl group (for example, a phenyl group, or a naphthyl group), a heteroaryl group (for example, a furyl group, a thienyl group, a pyridyl group, a pyridazyl group, a pyrimidyl group, a pyrazyl group, a triazyl group, an imidazolyl group, a pyrazolyl group, a thiazolyl group, a benzimidazolyl group, a benzoxazolyl group, a quinazolyl group, or a phthalazyl group), a saturated heterocyclic group (for example, a pyrrolidyl group, an imidazolidyl group, a morpholyl group or an oxazolidyl group), an alkoxy group (for example, a methoxy group, an ethoxy group, a propoxy group, a pentyloxy group, a hexyloxy group, an octyloxy group, or a dodecyloxy group), a cycloalkoxy group (for example, a cyclopentyloxy group, or a cyclohexyloxy group), an aryloxy group (for example, a phenoxy group or a naphthyloxy group), an alkylthio group (for example, a methylthio group, an ethylthio group, a propylthio group, a pentylthio group, a hexylthio group, an octylthio group, or a dodecylthio group), a cycloalkylthio group (for example, a cyclopentylthio group or a cyclohexylthio group), an arylthio group (for example, a phenylthio group, or a naphthylthio group), an alkoxycarbonyl group (for example, a methyloxycarbonyl group, an ethyloxycarbonyl group, a butyloxycarbonyl group, an octyloxycarbonyl group, or a dodecyloxycarbonyl group), an aryloxycarbonyl group (for example, a phenyloxycarbonyl group, or a naphthyloxycarbonyl group), a sulfamoyl group (for example, an aminosulfonyl group, a methylaminosulfonyl group, a dimethylaminosulfonyl group, a butylaminosulfonyl group, a hexylaminosulfonyl group, a cyclohexylaminosulfonyl group, an octylaminosulfonyl group, a dodecylaminosulfonyl group, a phenylaminosulfonyl group, a naphthylaminosulfonyl group, or a 2-pyridylaminosulfonyl group), an acyl group (for example, an acetyl group, an ethylcarbonyl group, a propylcarbonyl group, a pentylcarbonyl group, a cyclohexylcarbonyl group, an octylcarbonyl group, a 2-ethylhexylcarbonyl group, a dodecycarbonyl group, a phenylcarbonyl group, a naphthylcarbonyl group, or a pyridylcarbonyl group), an acyloxy group (for example, an acetyloxy group, an ethylcarbonyloxy group, a butylcarbonyloxy group, an octylcarbonyloxy group, a dodecycarbonyloxy group, or a phenylcarbonyloxy group), an amido group (for example, a methylcarbonylamino group, an ethylcarbonylamino group, a dimethylcarbonylamino group, a propylcarbonylamino group, a pentylcarbonylamino group, a cyclohexylcarbonylamino group, 2-ethylhexylcarbonylamino group, an octylcarbonylamino group, a a dodecycarbonylamino group, a phenylcarbonylamino group, or a naphthylcarbonylamino group), a carbamoyl group (for example, an aminocarbonyl group, a methylaminocarbonyl group, a dimethylaminocarbonyl group, a propylaminocarbonyl group, a pentylaminocarbonyl group, a cyclohexylaminocarbonyl group, an octylaminocarbonyl group, a 2-ethylhexylaminocarbonyl group, a dodecyaminocarbonyl group, a phenylaminocarbonyl group, a naphthylaminocarbonyl group, or a 2-pyridylaminocarbonyl group), a ureido group (for example, a methylureido group, an ethylureido group, a pentylureido group, a cyclohexylureido group, an octylureido group, a dodecylureido group, a phenylureido group, a naphthylureido group, or a 2-pyridylureido group), a sulfinyl group (for example, a methylsulfinyl group, an ethylsulfinyl group, a butylsulfinyl group, a cyclohexylsulfinyl group, a 2-ethylhexylsulfinyl group, a dodecylsulfinyl group, a phenylsulfinyl group, a naphthylsulfinyl group, or a 2-pyridylsulfinyl group), an alkylsulfonyl group (for example, a methylsulfonyl group, an ethylsulfonyl group, a butylsulfonyl group, a cyclohexylsulfonyl group, a 2-ethylhexylsulfonyl group, or a dodecylsulfonyl group), an arylsulfonyl group (for example, a phenylsulfonyl group, a naphthylsulfonyl group, or a 2-pyridylsulfonyl group), an amino group (for example, an amino group, an ethylamino group, a dimethylamino group, a butylaminocarbonyl group, a cyclopentylamino group, a 2-ethylhexylamino group, a dodecyamino group, an anilino group, a naphthylamino group, or a 2-pyridylamino group), a halogen atom (for example, fluorine, chlorine, or bromine), a cyano group, a nitro group, and a hydroxyl group. These substituents may have an additional substituent, and the additional substituent is the same as those denoted above. These substituents may be combined with each other to form a ring.

In R¹ of formula (1), the ratio of a total carbon atom number C₂ of the side chains to a total carbon atom number C₁ of the main chain, i., e, C₂/C₁ is preferably from 0.05 to 3.0. R¹ is preferably comprised of a main chain having a carbon atom number of 3 to 19 and at least one side chain having a carbon atom number of 1 to 9.

In formula (1), Z is preferably —NH—.

In formula (1), R² represents a substituted or unsubstituted alkylene group having a carbon atom number of from 1 to 10.

The substituent of the substituted alkylene group of R² is the same as those denoted in the substituted branched alkyl group of R¹. Plural R²s may be the same or different.

In formula (1), n represents an integer of 2 to 100.

The HLB value of the compound represented by formula (1) above is preferably from 11 to 15. The HLB value of not less than 11 renders the surfactant hydrophilic, and improves dispersibility in a developer of micelles in which a light sensitive material is incorporated, while the HLB value of not more than 15 renders the surfactant suitably lipophilic and maintains suitable permeation of a developer into a light sensitive material.

The HLB value herein referred to is a value showing a quantitative measure of the emulsification characteristics of a surfactant and numerically indicates the balance of hydrophilicity and lipophilicity of a surfactant. The HLB value is an abbreviation of the value of hydrophile and lipophile balance.

The HLB value can be determined according to several empirical equations proposed hitherto. The equations are as follows.

### (1) HLB of Polyoxyethylene-Type Nonionic Surfactant (Containing No Other Hydrophilic Group)

HLB=E/5

where E is a polyoxyethylene content (% by weight).

### (2) HLB of Ester of Polyhydric Alcohol and Fatty Acid

HLB=20(1−S/A)

where S is a saponification value of ester, and A is an acid value of fatty acid.

### (3) HLB of Tall Oil, Pine Oil, Bees Wax and Lanolin Polyhydric Alcohol

HLB=(E+P)/5

where E is oxyethylene content (% by weight), and P is a polyhydric alcohol content (% by weight).

### (4) HLB of Silicone-Containing Surfactant:

HLB=0.89×(cloud number A)+1.11

where the cloud number (A) can be determined in a manner such that when 0.5 g of a surfactant are dissolved in 5 ml of ethanol to obtain a surfactant ethanol solution and a 2% aqueous phenol solution is dropwise added thereto at 25° C., the milliliter number of the 2% aqueous phenol solution added till the end point when the solution becomes turbid is defined as cloud number A.

The HLB of a mixed surfactant of surfactant “a” exhibiting an HLB value of HLBa and surfactant “b” exhibiting an HLB value of HLBb is represented by the following formula:

HLB={(Wa×HLBa)+(Wb×HLBb)}/(Wa+Wb)

wherein Wa represents a weight fraction of surfactant a, and Wb represents a weight fraction of surfactant b.

In the invention, the HLB value is one calculated from equation (1) above.

Typical examples of compounds represented by formula (1) will be listed below, but the invention is not limited thereto.

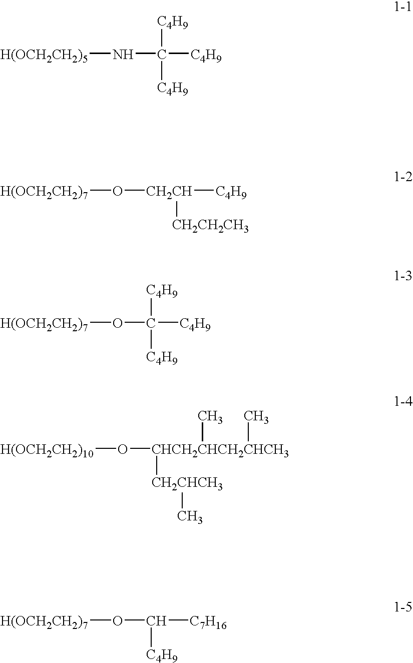

These compounds are commercially available and can be readily obtained. The content of the compound represented by formula (1) in a developer is not specifically limited, but is preferably from 0.01 to 20% by weight.

The developer of the invention can contain a water soluble resin in addition to the compound represented by formula (1) above. Examples of the water soluble resin include gum arabic, cellulose derivatives (e.g., carboxymethyl cellulose, carboxymethyl cellulose, methyl cellulose) and their modified compounds, polyvinyl alcohol and its derivatives, polyvinyl pyrrolidone, polyacrylamide and its copolymers, poly[(vinyl methyl ether)-co-(anhydrous maleic acid)], poly[(vinyl acetate)-co-(anhydrous maleic acid)], and poly[styrene-co-(anhydrous maleic acid)]. The content of the water soluble resin in the developer is preferably 0.1 to 50% by weight, and more preferably from 0.5 to 3.0% by weight.

The developer of the invention can contain various anionic and/or nonionic surfactants. For example, as the anionic surfactants, there are mentioned fatty acid salts, abietic acid salts, hydroxyalkane sulfonic acid salts, alkane sulfonic acid salts, dialkylsulfosuccinic acid salts, straight-chained alkylbenzene sulfonic acid salts, branched alkylbenzene sulfonic acid salts, alkylnaphthalene sulfonic acid salts, alkylphenoxypolyoxyethylenepropyl sulfonic acid salts, polyoxyethylenealkyl sulfophenylether salts, N-methyl-N-oleiltaurine sodium salts, N-alkylsulfosuccinic acid monoamide disodium salts, petroleum sulfonic acid salts, nitrated castor oil, sulfated beef tallow, fatty acid alkyl ester sulfate salts, alkylsulfate salts, polyoxyethylene alkyl ether sulfate salts, fatty acid monoglyceride sulfate salts, polyoxyethylene alkylphenyl ether sulfate salts, polyoxyethylene styrylphenyl ethersulfate salts, alkylphosphate salts, polyoxyethylene alkyl etherphosphate salts, polyoxyethylene alkylphenyl ether phosphate salts, partial saponification products of styrene-maleic anhydride copolymers, partial saponification products of olefin-maleic anhydride copolymers, and condensates of naphthalene sulfonic acid salts with formalin. Among these, dialkylsulfosuccinic acid salts, alkylsulfate salts and alkylnaphthalene sulfonic acid salts are preferably used.

As the nonnionic surfactants, there are mentioned polyoxyethylene alkyl ethers, polyoxyethylene alkylphenyl ethers, polyoxyethylene aryl ethers, polyoxyethylene naphthyl ethers, polyoxyethylene-polystyrylphenyl ethers, polyoxyethylenepolyoxypropylene alkyl ethers, partial esters of glycerin and fatty acids, partial esters of sorbitan and fatty acids, partial esters of pentaerythritol and fatty acids, propylene glycol monofatty acid ester, partial esters of sucrose and fatty acids, partial esters of polyoxyethylene sorbitan and fatty acids, partial esters of polyoxyethylene sorbitol and fatty acids, esters of polyoxyethylene glycol and fatty acids, partial esters of polyglycerin and fatty acids, polyoxyethylene castor oil, partial esters of polyoxyethyleneglyderin and fatty acid, diethanolamides, N,N-bis-2-hydroxyalkylamines, polyoxyethylenealkylamines, triethanolamine fatty acid esters, and trialkylamine oxides. Among these, polyoxyethylenealkylphenyl ethers, polyoxyethylenepolyoxypropylenalkyl ethers, and polyoxyethylene-polyoxypropylene block copolymer are preferably used.

Further, fluorine-containing or silicon-containing anionic surfactants or fluorine-containing or silicon-containing nonionic surfactants can be used.

As the preferred surfactants, there are mentioned surfactants as disclosed in Japanese Patent O.P.I. Publication Nos. 2004-167903 and 2004-230650 and 2005-43393, which are added in the protective solution.

These surfactants can be used as an admixture of two or more kinds thereof. For example, a combined use of two or more different anionic surfactants or a combined use of an anionic surfactant and a nonionic surfactant is preferred. The amount of the surfactant of the developer of the invention is not specifically limited, but it is preferably from 0.01 to 20% by weight.

The pH of the developer of the invention is in the range of from 3.0 to 9.0. When the developer within the acidic range of a pH of 3 to 6 is used, mineral acids, organic acids or inorganic salts are added thereto to adjust the pH to the range of 3 to 6. The addition amount is preferably in the range of 0.01 to 2% by weight. The mineral acids include, for example, nitric acid, sulfuric acid, phosphoric acid and metaphosphoric acid.

The organic acids include, for example, citric acid, acetic acid, oxalic acid, malonic acid, p-toluenesulfonic acid, tartaric acid, malic acid, lactic acid, levulinic acid, phytic acid and organic phosphonic acid.

The inorganic salts include, for example, magnesium nitrate, primary phosphate, secondary phosphate, nickel sulfate, sodium hexamethanate, and sodium tripolyphosphate. The mineral acids, organic acids and inorganic salts may be used alone or as a mixture of two or more kinds thereof.

When the developer within the basic range of a pH of 8 to 9 is used, water soluble organic or inorganic bases are added to thereto. Preferred examples of the water soluble organic bases include triethanolamine, diethanolamine and ethanolamine.

The developer of the invention may be added with antiseptics or defoaming agents. Examples of the antiseptics include phenol and its derivatives, formaline, imidazole derivatives, sodium dehydroacetate, 4-isothiazoline-3-one derivatives, benzoisothiazoline-3-one, benzotriazole derivatives, amidinoguanine derivatives, quaternary ammonium salts, derivatives of pyridine, quinoline and guanine, diazine, triazole derivatives, oxazole, and oxazine derivatives. A preferred content is a quantity capable of taking stable effect upon bacteria, mold or yeast, depending on the kind of bacteria, molds or yeast. The content is preferably 0.01 to 4% by weight, based on the working gum solution. Two or more antiseptic are preferably used as a mixture of two or more kinds thereof to take effects upon various kinds of bacteria or molds. Silicone defoaming agents are preferred, and any one of emulsion type and solubilization type is usable. A defoaming agent is used suitably at 0.01 to 1.0% by weight, based on the gum solution used.

Further, there may be added chelating agents. Preferred chelating agents include, for example, ethylenediaminetetraacetic acid and its sodium and potassium salts, diethylenetriaminepentaacetic acid and its sodium and potassium salts, triethylenetetraminehexaacetic acid and its sodium and potassium salts, ethylenediaminedisuccinic acid and its sodium and potassium salts, hydroxyethylethylenediaminetriacetic acid and its sodium and potassium salts, nitrilotriacetic acid and its sodium and potassium salts, and organic phosphonic acids or phosphonoalkanecarboxylic acids, such as 1-hydroxyethane-1,1-diphosphonic acid and its sodium and potassium salts, aminotri(methylenephosphonic acid) and its sodium and potassium salts. Besides the foregoing sodium and potassium salts of chelating agents, organic amine salts are also effective. Chelating agents are selected from those which can be stably present in the gum solution composition and is free from adverse effects on printing. The content thereof is preferably 0.001 to 1.0% by weight, based on the gum solution used.

In addition to the above ingredients, a lipophilicity-enhancing agent may be incorporated. Examples thereof include hydrocarbons such as turpentine oil, xylene, toluene, low heptane, solvent naphtha, kerosene, mineral spirit, petroleum fractions exhibiting a boiling point of ca. 120 to 250° C.; and plasticizers exhibiting a freezing point of 15° C. or less and a boiling point of 300° C. or more at 1 atmospheric pressure, including phthalic acid diesters such as dibutyl phthalate, diheptyl phthalate, di-n-octyl phthalate, di(2-ethylhexyl)phthalate, dinonyl phthalate, didecyl phthalate, dilauryl phthalate, and butylbenzyl phthalate; dibasic fatty acid esters, such as dioctyl adipate, butylglycol adipate, dioctyl azelate, dibutyl sebacate, di(2-ethylhexyl)sebacate, and diocyl sebacate; epoxy-modified triglycerides such as epoxy-modified soybean oil; phosphoric acid esters such as tricresyl phosphate, trioctyl phosphate, and triscrolethyl phosphate; and benzoic acid esters such as benzyl benzoate.

Further, there are included saturated fatty acids such as caproic acid, enatoic acid, heralgonic acid, capric acid, undecylic acid, lauric acid, tridecylic acid, myristic acid, pentadecylic acid, palmitic acid, heptadecylic acid, stearic acid, nonadecanoic acid, arachic acid, behenic acid, lignoceric acid, cerotic acid, heptacosanoic acid, montanic acid, melissic acid, lacceric acid, and iso-valeric acid; and unsaturated fatty acids such as acrylic acid, crotonic acid, isocrotonic acid, undecylenic acidpleic acid, elaidic acid, cetoleic acid, nilcaic acid, btecidinic acid, sorbic acid, linolic acid, linolenic acid, arachidonic acid, propiolic acid, stearolic acid, sardine oil, tariric acid, and licanic acid. Of the foregoing, a fatty acid which is liquid at 50° C. is more preferred, one having 5 to 25 carbons is still more preferred, and one having 8 to 21 carbons is most preferred. These lipophilicity-enhancing agents may be used alone or as a mixture of two or more kinds thereof. The content thereof is preferably 0.01 to 10%, and more preferably 0.05 to 5% by weight, based on the developer.

(Co-initiator: Compound Represented by formula (2))

The light sensitive layer of the light sensitive planographic printing plate material in the invention preferably contains a compound represented by formula (2) as a co-initiator.

Herein, the co-initiator refers to a compound having function promoting polymerization reaction initiated by reaction of a polymerization initiator described later.

The compound represented by formula (2) is preferably a compound represented by formula (3), (4), (5), (6) or (7) below.

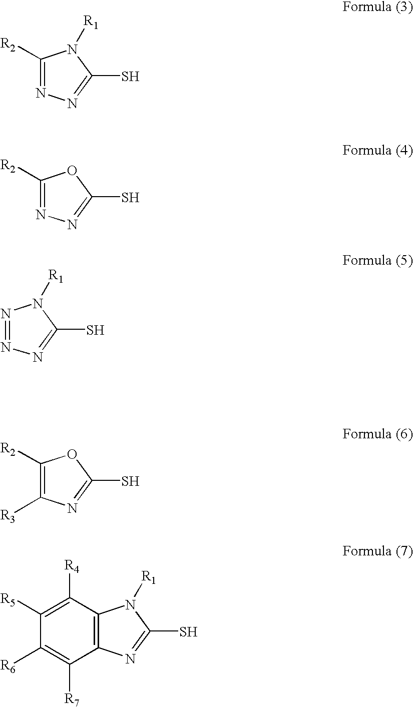

In formulae (3) through (7); R₁ through R₃ independently represent a substituted or unsubstituted alkyl group or a substituted or unsubstituted aryl group, and R₄ through R₇ independently represent a hydrogen atom, a halogen atom, an alkoxy group, an alkylamino group, a dialkylamino group, a substituted or unsubstituted alkyl group or a substituted or unsubstituted aryl group.

The substituted or unsubstituted alkyl group described above is not specifically limited, but examples thereof include a straight chained, branched or cyclic alkyl group such as methyl, ethyl, n-propyl, iso-propyl, n-butyl, iso-butyl, tert-butyl, n-pentyl, n-hexyl, cyclohexyl, 2-ethylkexyl, octyl, nonyl, decyl and a straight chained, branched or cyclic alkyl group having a substituent. The substituent is not specifically limited, but examples thereof include an alkoxy group, an alkylamino group, a dialkylamino group, a halogen atom, an aryl group and an aralkyl group.

Preferred examples of the alkyl group include methyl, ethyl, n-butyl, tert-butyl, methoxymethyl, methoxyethyl, benzyl and chloromethyl.

The substituted or unsubstituted aryl group described above is not specifically limited, but examples thereof include a phenyl group and a naphthyl group, each of which may have a substituent. The substituent is not specifically limited, but examples thereof include an alkyl group, an alkoxy group, an alkylamino group, a dialkylamino group, a halogen atom, an aryl group and an aralkyl group.

Preferred examples of the aryl group include phenyl, tolyl, methoxyphenyl, chlorophenyl, t-butylphenyl, and dialkylaminophenyl.

Typical examples of a compound represented by formula (3), (4), (5), (6), or (7) will be listed below, but the invention is not limited thereto.

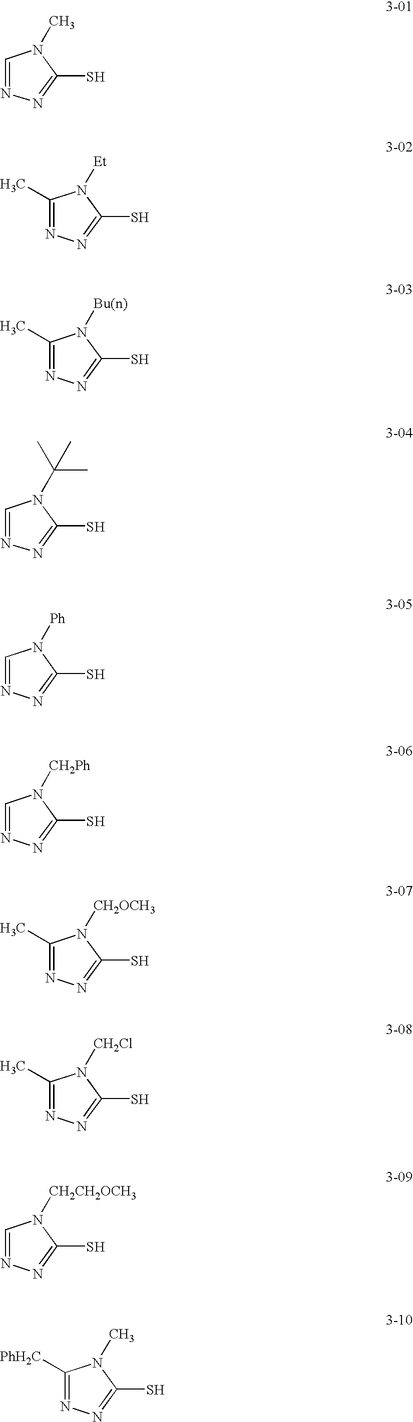

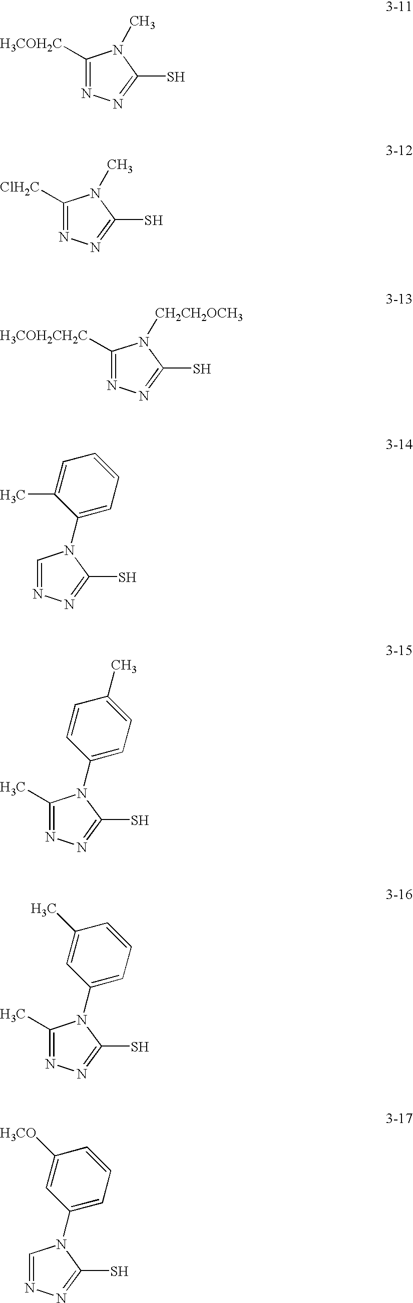

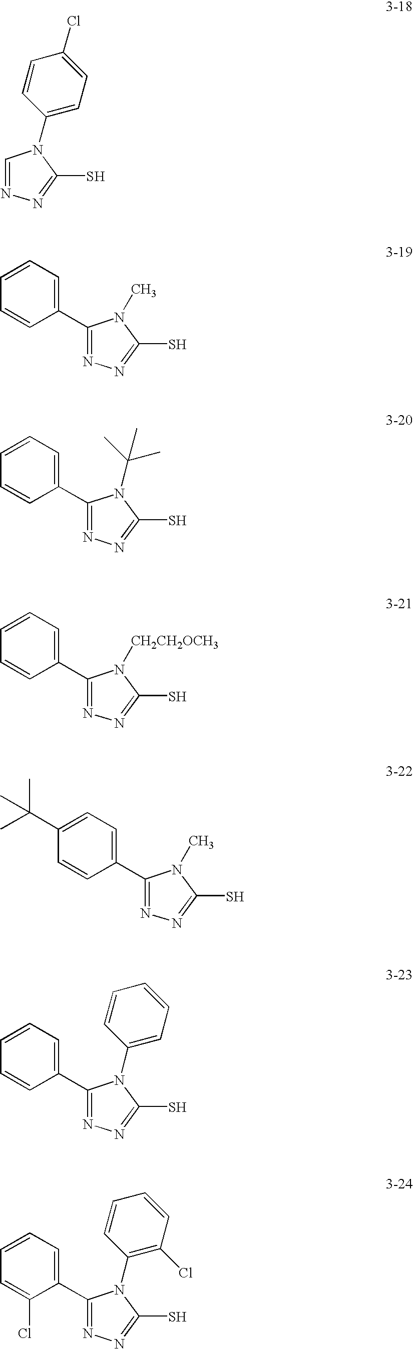

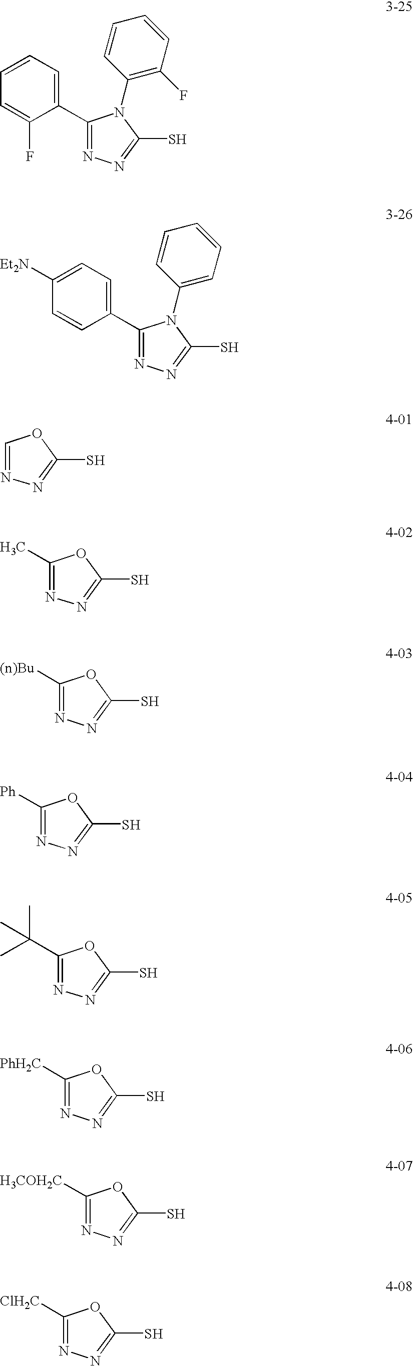

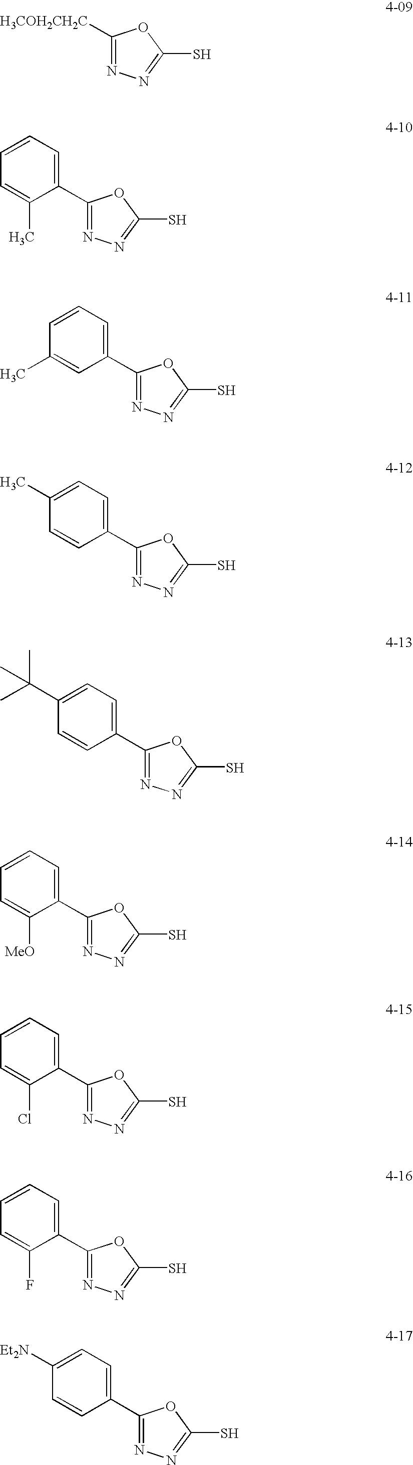

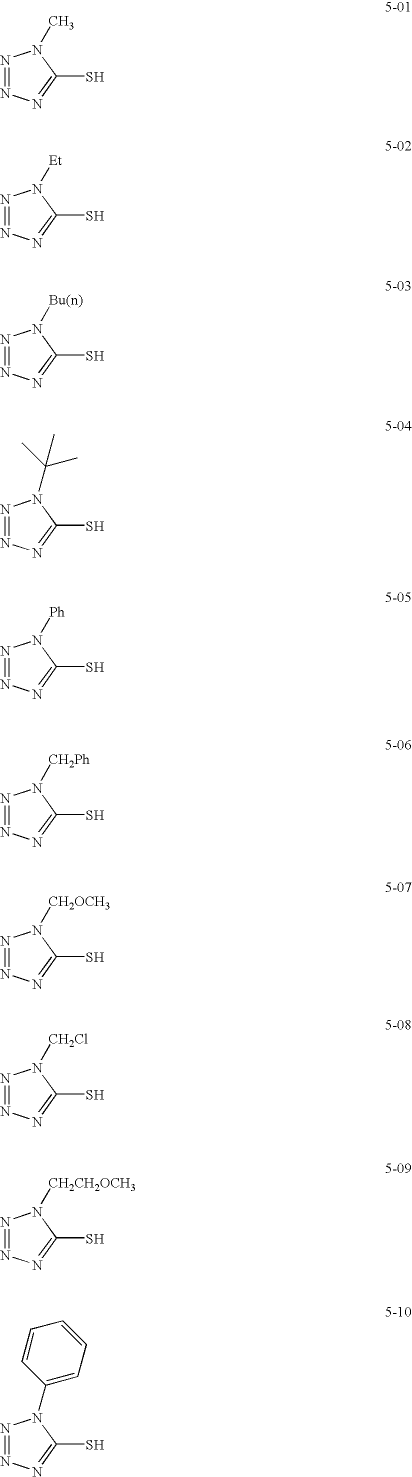

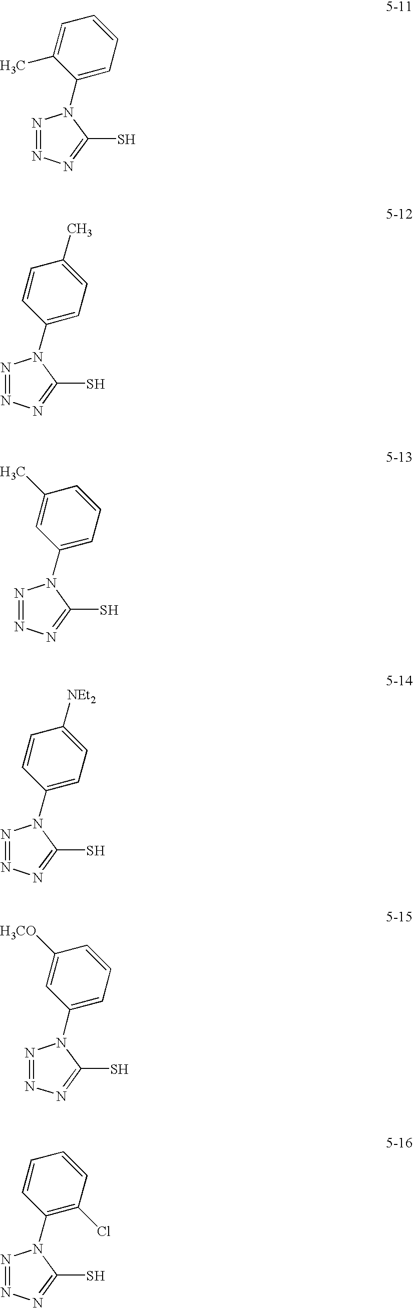

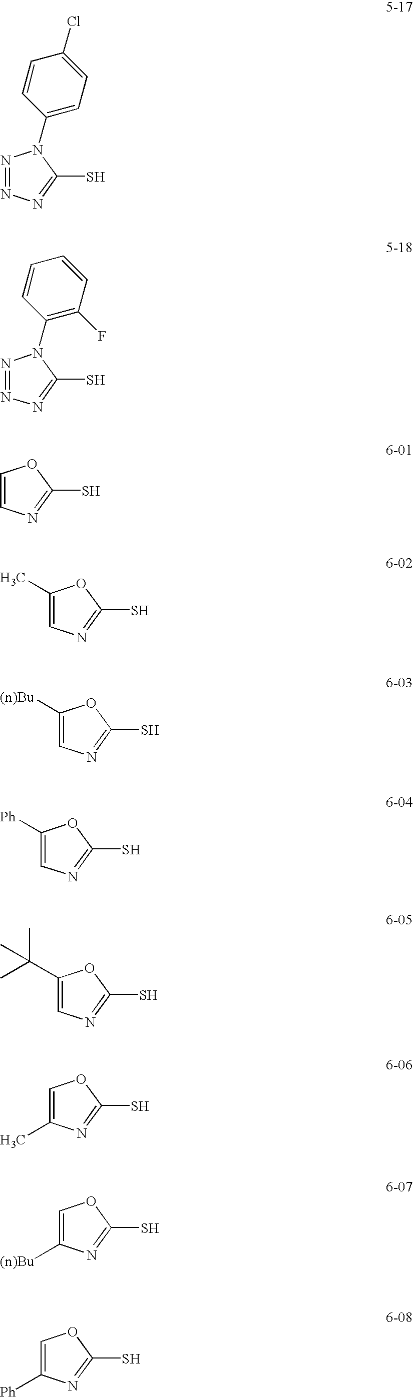

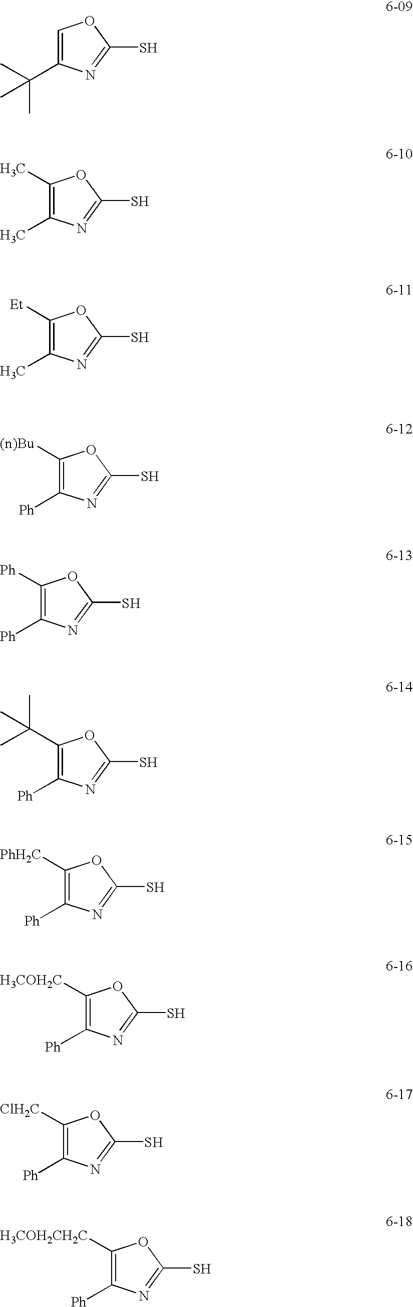

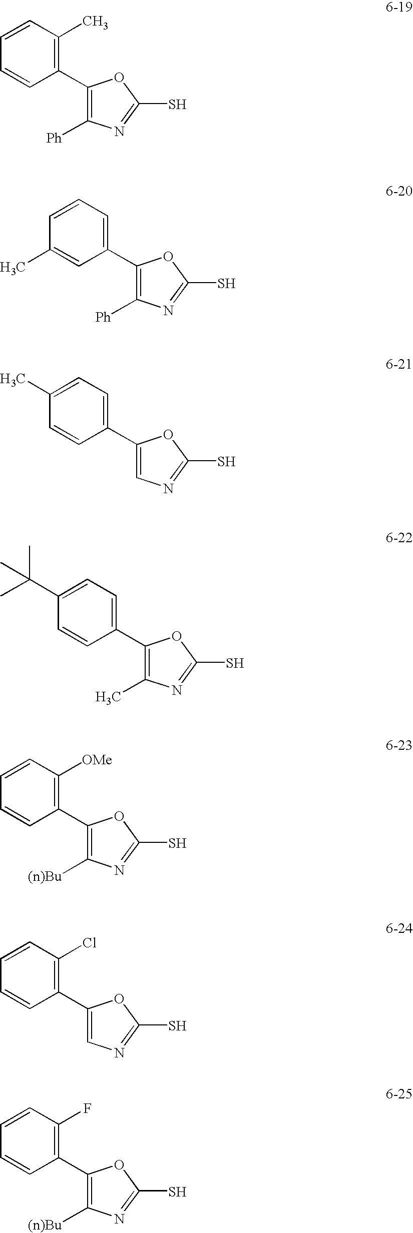

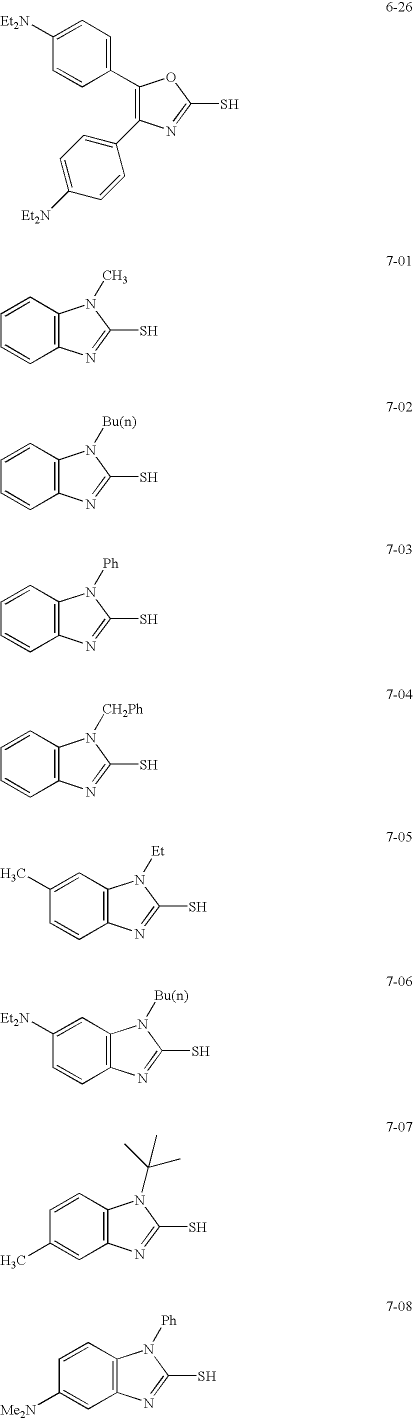

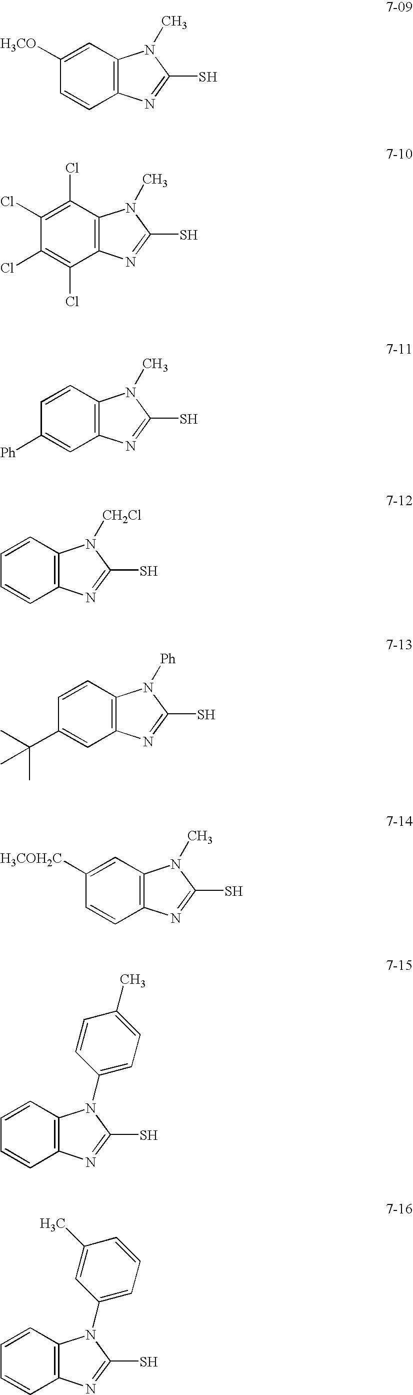

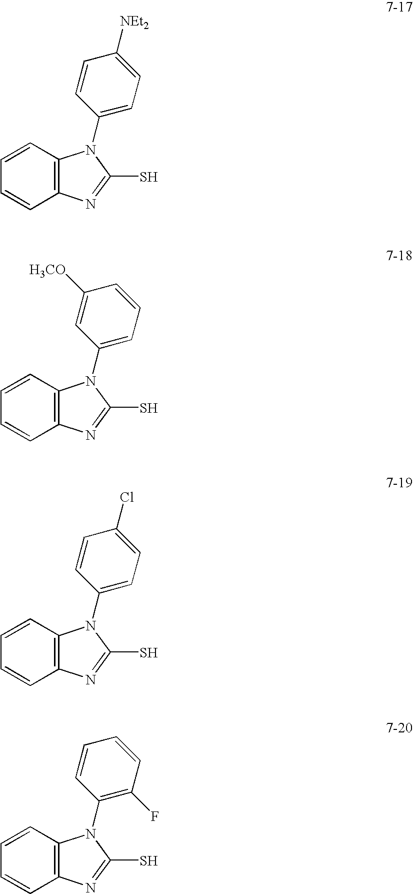

The content of the compound represented by formula (3), (4), (5), (6), or (7) in the light sensitive layer is preferably from 0.01 to 20% by weight, more preferably from 0.1 to 15% by weight, and still more preferably from 1.0 to 10% by weight, based on the total solid content of the light sensitive layer.

In the invention, various conventional co-initiators, for example, co-initiators as disclosed in Japanese Patent O.P.I. Publication Nos. 08-254821 and 2005-062482 can be used.

### (Polymerization Initiator)

The polymerization initiator in the invention is a compound which initiates polymerization of a polymerizable monomer such as an ethylenically unsaturated compound on light exposure. In the invention, a hexaarylbiimidazole compound is preferably used as a polymerization initiator.

The synthetic method of the hexaarylbiimidazole compound (HABI, a dimer of triarylimidazole)used in the invention is disclosed in DE 1470154, and use thereof in a photopolymerizable composition is disclosed in EP 24629, EP 107792, U.S. Pat. No. 4,410,621, EP 215453 and DE 3211312.

Preferred examples of the hexaarylbiimidazole compound include 2,4,5,2′,4′,5′-hexaphenylbiimidazole, 2,2′-bis(2-chlorophenyl)-4,5,4′,5′-tetraphenylbiimidazole, 2,2′-bis(2-bromophenyl)-4,5,4′,5′-tetraphenylbiimidazole, 2,2′-bis(2,4-dichlorophenyl)-4,5,4′,5′-tetraphenyl-biimidazole, 2,2′-bis(2-chlorophenyl)-4,5,4′,5′-tetrakis(3-methoxyphenyl)biimidazole, 2,2′-bis(2-chlorophenyl)-4,5,4′,5′-tetrakis-(3,4,5-trimethoxyphenyl)biimidazole, 2,5,2′,5′-tetrakis(2-chlorophenyl)-4,4′-bis(3,4-dimethoxyphenyl)biimidazole, 2,2′-bis(2,6-dichlorophenyl)-4,5,4′,5′-tetraphenylbiimidazole, 2,2′-bis(2-nitrophenyl)-4,5,4′,5′-tetraphenylbiimidazole, 2,2′-di-o-tolyl-4,5,4′,5′-tetraphenylbiimidazole, 2,2′-bis(2-ethoxyphenyl)-4,5,4′,5′-tetraphenylbiimidazole, and 2,2′-bis(2,6-difluorophenyl)-4,5,4′,5′-tetraphenylbiimidazole.

In the invention, other polymerization initiators can be used in addition to the hexaarylbiimidazole compound above. Examples thereof include a titanocene compound, a monoalkyltriaryl borate compound, an iron arene complex and a polyhalogenated compound.

The titanocene compounds include those described in Japanese Patent O.P.I. Publication Nos. 63-41483 and 2-291. Preferred examples of the titanocene compounds include bis(cyclopentadienyl)-Ti-di-chloride, bis(cyclopentadienyl)-Ti-bis-phenyl, bis(cyclopentadienyl)-Ti-bis-2,3,4,5,6-pentaflurophenyl, bis(cyclopentadienyl)-Ti-bis-2,3,5,6-tetrafluorophenyl, bis(cyclopentadienyl)-Ti-bis-2,4,6-trifluorophenyl, bis(cyclopentadienyl)-Ti-bis-2,6-difluorophenyl, bis(cyclopentadienyl)-Ti-bis-2,4-difluorophenyl, bis(methylcyclopentadienyl)-Ti-bis-2,3,4,5,6-pentafluorophenyl, bis(methylcyclopentadienyl)-Ti-bis-2,3,5,6-tetrafluorophenyl, bis(methylcyclopentadienyl)-Ti-bis-2,6-difluorophenyl (IRUGACURE 784, produced by Ciba Speciality Chemicals Co.), bis(cyclopentadienyl)-bis(2,4,6-trifluoro-3-(pyry-1-yl)phenyl)titanium, and bis(cyclopentadienyl)-bis(2,4,6-trifluoro-3-(2-5-dimethylpyry-1-yl)phenyl)titanium.

As the monoalkyltriaryl borate compound, there are those described in Japanese Patent O.P.I. Publication Nos. 62-150242 and 62-143044. Preferred examples of the monoalkyl-triaryl borate compounds include tetra-n-butyl ammonium n-butyltrinaphthalene-1-yl-borate, tetra-n-butylammonium n-butyltriphenylborate, tetra-n-butylammonium triphenyl-mono-t-butylborate, tetra-n-butylammonium n-butyl-tri-(4-tert-butylphenyl)borate, tetra-n-butylammonium n-hexyl-tri-(3-chloro-4-methylphenyl)borate, and tetra-n-butylammonium n-hexyl-tri-(3-fluorophenyl)borate.

As the iron arene complexes, there are those described in Japanese Patent O.P.I. Publication No. 59-219307. Preferred examples of the iron arene complex include η-benzene-(η-cyclopentadienyl)iron hexafluorophosphate, η-cumene-(η-cyclopentadienyl)iron hexafluorophosphate, η-fluorene-(η-cyclopentadienyl)iron hexafluorophosphate, η-naphthalene-(η-cyclopentadienyl)iron hexafluorophosphate, η-xylene-(η-cyclopentadienyl)iron hexafluorophosphate, and η-benzene-(η-cyclopentadienyl)iron tetrafluoroborate;

As the polyhalogenated compound, a compound having a trihalomethyl group, a dihalomethyl group or a dihalomethylene group is preferably used. In the invention, an oxadiazole compound having in the molecule the group described above as the substituent or a polyhalogenated compound represented by the following formula (PIH1) is preferably used.

Among these, a polyhalogenated compound represented by the following formula (PIH2) is especially preferably used.

R¹¹—C(Y)₂—(C═O)—R¹² Formula (PIH1)

wherein R¹¹ represents a hydrogen atom, a halogen atom, an alkyl group, an aryl group, an acyl group, an alkylsulfonyl group, an arylsulfonyl group, an iminosulfo group or a cyano group; R¹² represents a monovalent substituent, provided that R¹¹ and R¹² may combine with each other to form a ring; and Y represents a halogen atom.

C(Y)₃—(C═O)—X—R¹³ Formula (PIH2)

wherein R¹³ represents a monovalent substituent; X represents —O— or —NR¹⁴— in which R¹⁴ represents a hydrogen atom or an alkyl group, provided that when X represents —NR¹⁴—, R¹⁴ and R¹⁴ may combine with each other to form a ring; and Y represents a halogen atom.

Among these, a polyhalogenated compound having a polyhaloacetylamide group is preferably used.

An oxadiazole compound having a polyhalomethyl group as the substituent also is preferably used. Further, oxadiazole compounds disclosed in Japanese Patent O.P.I. Publication Nos. 5-34904, 5-45875 and 8-240909 are preferably used.

Another photopolymerization initiator can be used in combination. Examples thereof include carbonyl compounds, organic sulfur compounds, peroxides, redox compounds, azo or diazo compounds, halides and photo-reducing dyes disclosed in J. Kosar, “Light Sensitive Systems”, Paragraph 5, and those disclosed in British Patent No. 1,459,563.

Typical examples of the photopolymerization initiator used in combination include the following compounds:

A benzoin derivative such as benzoin methyl ether, benzoin i-propyl ether, or α,α-dimethoxy-α-phenylacetophenone; a benzophenone derivative such as benzophenone, 2,4-dichlorobenzophenone, o-benzoyl methyl benzoate, or 4,4′-bis (dimethylamino) benzophenone; a thioxanthone derivative such as 2-chlorothioxanthone, 2-i-propylthioxanthone; an anthraquinone derivative such as 2-chloroanthraquinone or 2-methylanthraquinone; an acridone derivative such as N-methylacridone or N-butylacridone; α,α-diethoxyacetophenone; benzil; fluorenone; xanthone; an uranyl compound; a triazine derivative disclosed in Japanese Patent Publication Nos. 59-1281 and 61-9621 and Japanese Patent O.P.I. Publication No. 60-60104; an organic peroxide compound disclosed in Japanese Patent O.P.I. Publication Nos. 59-1504 and 61-243807; a diazonium compound in Japanese Patent Publication Nos. 43-23684, 44-6413, 47-1604 and U.S. Pat. No. 3,567,453; an organic azide compound disclosed in U.S. Pat. Nos. 2,848,328, 2,852,379 and 2,940,853; orthoquinondiazide compounds disclosed in Japanese Patent Publication Nos. 36-22062b, 37-13109, 38-18015 and 45-9610; various onium compounds disclosed in Japanese Patent Publication No. 55-39162, Japanese Patent O.P.I. Publication No. 59-14023 and “Macromolecules”, Volume 10, p. 1307 (1977); azo compounds disclosed in Japanese Patent Publication No. 59-142205; metal arene complexes disclosed in Japanese Patent O.P.I. Publication No. 1-54440, European Patent Nos. 109, 851 and 126, 712, and “Journal of Imaging Science”, Volume 30, p. 174 (1986); (oxo) sulfonium organoboron complexes disclosed in Japanese Patent O.P.I. Publication Nos. 5-213861 and 5-255347; titanocenes disclosed in Japanese Patent O.P.I. Publication Nos. 59-152396 and 61-151197; transition metal complexes containing a transition metal such as ruthenium disclosed in “Coordination Chemistry Review”, Volume 84, p. 85-277 (1988) and Japanese Patent O.P.I. Publication No. 2-182701; 2,4,5-triarylimidazol dimmer disclosed in Japanese Patent O.P.I. Publication No. 3-209477; carbon tetrabromide; organic halide compounds disclosed in Japanese Patent O.P.I. Publication No. 59-107344.

The content of the polymerization initiator in the light sensitive layer is preferably from 0.1 to 20% by weight, and more preferably from 0.5 to 15% by weight, based on the total content of a polymerizable compound described later.

### (Polymerizable Compound)

The polymerizable compound is a compound capable of polymerizing by a reaction product of a polymerization initiator produced on imagewise exposure. As the polymerizable compound, a wide range of compounds can be used which are capable of initiating polymerization by reaction with radicals generated from the polymerization initiator in the invention.

As the polymerizable compound in the invention, an ethylenically unsaturated compound is preferably used. Examples of the ethylenically unsaturated compound include conventional radically polymerizable monomers, and polyfunctional monomers and polyfunctional oligomers each having plural ethylenically unsaturated bond ordinarily used in UV-curable resins.

The polymerizable compound in the invention is not specifically limited, but preferred examples thereof include a monofunctional acrylate such as 2-ethylhexyl acrylate, 2-hydroxypropyl acrylate, glycerol acrylate, tetrahydrofurfuryl acrylate, phenoxyethyl acrylate, nonylphenoxyethyl acrylate, tetrahydrofurfuryloxyethyl acrylate, tetrahydrofurfuryloxyhexyl acrylate, or 1,3-dioxolanyl acrylate; a methacrylate, itaconate, crotonate or maleate alternative of the above acrylate; a bifunctional acrylate such as ethyleneglycol diacrylate, triethyleneglycol diacrylate, pentaerythritol diacrylate, hydroquinone diacrylate, resorcin diacrylate, hexanediol diacrylate, neopentyl glycol diacrylate, tripropylene glycol diacrylate, hydroxypivalic acid neopentyl glycol diacrylate, neopentyl glycol adipate diacrylate, diacrylate of hydroxypivalic acid neopentyl glycol-ε-caprolactone adduct, 2-(2-hydroxy-1,1-dimethylethyl)-5-hydroxymethyl-5-ethyl-1,3-dioxane diacrylate, tricyclodecanedimethylol acrylate, tricyclodecanedimethylol acrylate-ε-caprolactone adduct or 1,6-hexanediol diglycidylether diacrylate; a dimethacrylate, diitaconate, dicrotonate or dimaleate alternative of the above diacrylate; a polyfunctional acrylate such as trimethylolpropane triacrylate, ditrimethylolpropane tetraacrylate, trimethylolethane triacrylate, pentaerythritol triacrylate, pentaerythritol tetraacrylate, dipentaerythritol tetraacrylate, dipentaerythritol pentaacrylate, dipentaerythritol hexacrylate, dipentaerythritol hexacrylate-ε-caprolactone adduct, pyrrogallol triacrylate, propionic acid dipentaerythritol triacrylate, propionic acid dipentaerythritol tetraacrylate, hydroxypivalylaldehyde modified dimethylolpropane triacrylate or EO-modified products thereof; and a methacrylate, itaconate, crotonate or maleate alternative of the above polyfunctional acrylate.

A prepolymer can be used as the polymerizable monomer described above. Examples of the prepolymer include compounds described later and prepolymers with a photopolymerization property obtained by incorporating an acryloyl or methacryloyl group into a prepolymer with an appropriate molecular weight. These prepolymers can be used singly or as an admixture of the above described monomers and/or oligomers.

Examples of the prepolymer include polyester (meth)acrylate obtained by incorporating (meth)acrylic acid in a polyester of a polybasic acid such as adipic acid, trimellitic acid, maleic acid, phthalic acid, terephthalic acid, hymic acid, malonic acid, succinic acid, glutaric acid, itaconic acid, pyromellitic acid, fumalic acid, pimelic acid, sebatic acid, dodecanic acid or tetrahydrophthalic acid with a polyol such as ethylene glycol, ethylene glycol, diethylene glycol, propylene oxide, 1,4-butane diol, triethylene glycol, tetraethylene glycol, polyethylene glycol, grycerin, trimethylol propane, pentaerythritol, sorbitol, 1,6-hexanediol or 1,2,6-hexanetriol; an epoxyacrylate such as bisphenol A•epichlorhydrin•(meth)acrylic acid or phenol novolak•epichlorhydrin•(meth)acrylic acid obtained by incorporating (meth)acrylic acid in an epoxy resin; an urethaneacrylate such as ethylene glycol•adipic acid•tolylenediisocyanate•2-hydroxyethylacrylate, polyethylene glycol•tolylenediisocyanate•2-hydroxyethylacrylate, hydroxyethylphthalyl methacrylate•xylenediisocyanate, 1,2-polybutadieneglycol•tolylenediisocyanate•2-hydroxyethylacrylate or trimethylolpropane•propylene glycol•tolylenediisocyanate•2-hydroxyethylacrylate, obtained by incorporating (meth)acrylic acid in an urethane resin; a silicone acrylate such as polysiloxane acrylate, or polysiloxane•diisocyanate•2-hydroxyethylacrylate; an alkyd modified acrylate obtained by incorporating a methacroyl group in an oil modified alkyd resin; and a spiran resin acrylate.

The light sensitive layer can contain a monomer such as a phosphazene monomer, triethylene glycol, an EO modified isocyanuric acid diacrylate, an EO modified isocyanuric-acid triacrylate, dimethyloltricyclodecane diacrylate, trimethylolpropane acrylate benzoate, an alkylene glycol acrylate, or a urethane modified acrylate, or an addition polymerizable oligomer or prepolymer having a structural unit derived from the above monomer.

As the ethylenically unsaturated compound used in combination in the light sensitive layer, there is a phosphate compound having at least one (meth)acryloyl group. The phosphate compound is a compound having a (meth)acryloyl group in which at least one hydroxyl group of phosphoric acid is esterified, but is not limited as long as it has a (meth)acryloyl group.

Besides the above compounds, compounds disclosed in Japanese Patent O.P.I. Publication Nos. 58-212994, 61-6649, 62-46688, 62-48589, 62-173295, 62-187092, 63-67189, and 1-244891, compounds described on pages 286 to 294 of “11290 Chemical Compounds” edited by Kagakukogyo Nipposha, and compounds described on pages 11 to 65 of “UV•EB Koka Handbook (Materials)” edited by Kobunshi Kankokai can be suitably used. Of these compounds, compounds having two or more acryl or methacryl groups in the molecule are preferable, and those having a molecular weight of not more than 10,000, and preferably not more than 5,000 are more preferable.

It is preferred in the invention that the light sensitive layer contains, as a polymerizable compound, an ethylenically unsaturated compound having a tertiary amino group in the molecule (a tertiary amine monomer). The tertiary amine monomer is not specifically limited to the chemical structure, but is preferably a hydroxyl group-containing tertiary amine modified with glycidyl methacrylate, methacrylic acid chloride or acrylic acid chloride. Typically, a polymerizable compound is preferably used which is disclosed in Japanese Patent O.P.I. Publication Nos. 1-165613, 1-203413 and 1-197213.

In the invention, a reaction product of a polyhydric alcohol having a tertiary amino group in the molecule, a diisocyanate and a compound having both a hydroxyl group and an addition polymerizable ethylenically double bond in the molecule is preferably used as the tertiary amine monomer. A compound having a tertiary amino group and an amide bond in the molecule is especially preferred.

Examples of the polyhydric alcohol having a tertiary amino group in the molecule include triethanolamine, N-methyldiethanolamine, N-ethyldiethanolamine, N-ethyldiethanolamine, N-n-butyldiethanolamine, N-tert-butyldiethanolamine, N,N-di(hydroxyethyl)aniline, N,N,N′,N′-tetra-2-hydroxypropylethylenediamine, p-tolyldiethanolamine, N,N,N′,N′-tetra-2-hydroxyethylethylenediamine, N,N-bis(2-hydroxypropyl)aniline, allyldiethanolamine, 3-dimethylamino-1,2-propane diol, 3-diethylamino-1,2-propane diol, N,N-di(n-propylamino)-2,3-propane diol, N,N-di(iso-propylamino)-2,3-propane diol, and 3-(N-methyl-N-benzylamino)-1,2-propane diol, but the invention is not specifically limited thereto.

Examples of the diisocyanate include butane-1,4-diisocyanate, hexane-1,6-diisocyanate, 2-methylpentane-1,5-diisocyanate, octane-1,8-diisocyanate, 1,3-diisocyanatomethylcyclohexanone, 2,2,4-trimethylhexane-1,6-diisocyanate, isophorone diisocyanate, 1,2-phenylene diisocyanate, 1,3-phenylene diisocyanate, 1,4-phenylene diisocyanate, tolylene-2,4-diisocyanate, tolylene-2,5-diisocyanate, tolylene-2,6-diisocyanate, 1,3-di(isocyanatomethyl)benzene, and 1,3-bis(1-isocyanato-1-methylethyl)benzene, but the invention is not specifically limited thereto.

Examples of the compound having a hydroxyl group and an addition polymerizable ethylenically double bond in the molecule is not specifically limited, but 2-hydroxyethyl methacrylate (MH-1), 2-hydroxyethyl acrylate (MH-2), 4-hydroxybutyl acrylate (MH-4), 2-hydroxypropylene-1,3-dimethacrylate (MH-7), and 2-hydroxypropylene-1-methacrylate-3-acrylate (MH-8) are preferred.

Examples of the reaction product of a polyhydric alcohol having a tertiary amino group in the molecule, a diisocyanate, and a compound having a hydroxyl group and an addition polymerizable ethylenically double bond in the molecule will be listed below.

The reaction product can be synthesized according to the same method as a conventional method in which a urethaneacrylate compound is ordinarily synthesized employing a diol, a diisocyanate and an acrylate having a hydroxyl group.
M-1: A reaction product of triethanolamine (1 mole), hexane-1,6-diisocyanate (3 moles), and 2-hydroxyethyl methacrylate (3 moles)
M-2: A reaction product of triethanolamine (1 mole), isophorone diisocyanate (3 moles), and 2-hydroxyethyl methacrylate (3 moles)
M-3: A reaction product of N-n-butyldiethanolamine (1 mole), 1,3-bis(1-cyanato-1-methylethyl)benzene (2 moles), and 2-hydroxypropylene-1-methacrylate-3-acrylate (2 moles)
M-4: A reaction product of N-n-butyldiethanolamine (1 mole), 1,3-di(cyanatomethyl)benzene (2 moles), and 2-hydroxypropylene-1-methacrylate-3-acrylate (2 moles)
M-5: A reaction product of N-methydiethanolamine (1 mole), tolylene-2,4-diisocyanate (2 moles), and 2-hydroxypropylene-1,3-dimethacrylate (2 moles)

In addition to the above, acrylates or methacrylates disclosed in Japanese Patent O.P.I. Publication Nos. 1-105238 and 2-127404 can be used.

In the invention, among these polymerizable compounds, a polymerizable compound having in the molecule a hydroxyl group (hereinafter also referred to as hydroxyl group-containing polymerizable compound) is especially preferred in solving the problems raised previously.

The hydroxyl group-containing polymerizable compound is preferably a compound represented by formula (8) below.

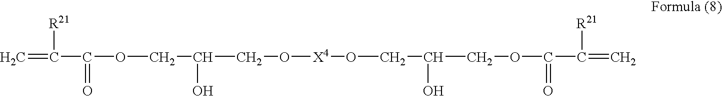

wherein R²¹ represents a hydrogen atom or a methyl group; and X⁴ represents —CH₂C(R²²)(R²³)—CH₂—, —(CH₂—CH(OR²⁴)—CH₂—O)m-CH₂—CH(OR²⁵)CH₂—, —(CH(R²⁶)CH₂O)n-CH(R²⁶)CH₂—, —CO—X²—CO— or —X²—, in which R²² and R²³ independently represent a hydrogen atom or a substituted or unsubstituted alkyl group, R²⁴, R²⁵ and R²⁶ independently represent a hydrogen atom or an alkyl group, X² represents an arylene group, an alkylene group or a cycloalkylene group, and m and n independently represent an integer of from 1 to 20.

Typical examples of the alkyl group of R²² through R²⁶ above include a methyl group, an ethyl group, a propyl group, an isopropyl group, a tert-butyl group, a pentyl group, a hexyl group and an octyl group. Among these alkyl groups, an alkyl group with a carbon atom number of from 1 to 10 is preferred, and an alkyl group with a carbon atom number of from 1 to 5 is more preferred. It is especially preferred that the alkyl group of R²² and R²³ is an alkyl group having a carbon atom number of from 1 to 4. It is especially preferred that the alkyl group of R²⁴ through R²⁶ is a methyl group.

Examples of the substituent of the substituted alkyl group include an aryl group (for example, a phenyl group or a naphthyl group); an alkoxy group (for example, a methoxy group, an ethoxy group, a propoxy group, a pentyloxy group, or a hexyloxy group); an alkoxycarbonyl group (for example, a methyloxycarbonyl group, an ethyloxycarbonyl group, or a butyloxycarbonyl group); an acyl group (for example, an acetyl group, an ethylcarbonyl group, a propylcarbonyl group, a pentylcarbonyl group, or a cyclohexylcarbonyl group); an amido group (for example, a methylcarbonylamino group, an ethylcarbonylamino group, a dimethylcarbonylamino group, a propylcarbonylamino group, a pentylcarbonylamino group, a cyclohexylcarbonylamino group, or 2-ethylhexylcarbonylamino group); an amino group (for example, an amino group, an ethylamino group, a dimethylamino group, a butylamino group, a cyclopentylamino group, a 2-ethylhexylamino group, an anilino group, a naphthylamino group, or a 2-pyridylamino group); a halogen atom (for example, fluorine, chlorine, or bromine); and a hydroxyl group.

Among these substituents, an aryl group, an amino group, an amido group, an alkoxycarbonyl group or a hydroxyl group is preferred.

Examples of the alkylene group of X² include an ethylene group, a trimethylene group, a tetramethylene group, a propylene group, an ethylethylene group, a pentamethylene group, a hexamethylene group, and a 2,2,4-trimethylhexamethylene group. Examples of the cycloalkylene group of X² include a cyclopentylene group and a cyclohexylene group. Examples of the arylene group of X² include a phenylene group and a naphthylene group.

Examples of a compound represented by formula (8) will be listed below, but the invention is not limited thereto.

| | R²¹ | X⁴ |
|---|---|---|
| 8-1 | —H | 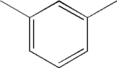 |
| 8-2 | —H | 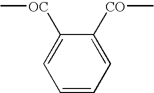 |
| 8-3 | —H | 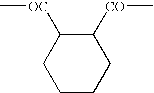 |
| 8-4 | —H | 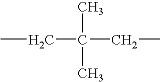 |
| 8-5 | —H | 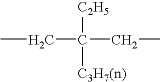 |
| 8-6 | —H | 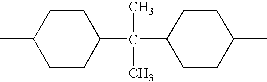 |
| 8-7 | —H | 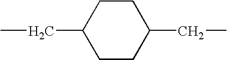 |
| 8-8 | —H | —(CH₂)₄— |
| 8-9 | —H | —(CH₂)₆— |
| 8-10 | —H | —CH₂CH₂— |
| 8-11 | —H | —CH₂CH₂OCH₂CH₂— |
| 8-12 | —H | —(CH₂CH₂O)₃CH₂CH₂— |
| 8-13 | —H | —(CH₂CH₂O)₈CH₂CH₂— |
| 8-14 | —H | —(CH₂CH₂O)₁₂CH₂CH₂— |
| 8-15 | —CH₃ | 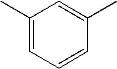 |
| 8-16 | —CH₃ | 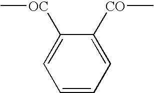 |
| 8-17 | —CH₃ | 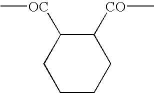 |
| 8-18 | —CH₃ | 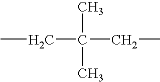 |
| 8-19 | —CH₃ | 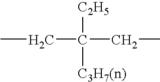 |
| 8-20 | —CH₃ | 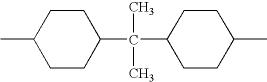 |
| 8-21 | —CH₃ | 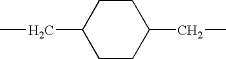 |
| 8-22 | —CH₃ | —(CH₂)₄— |
| 8-23 | —CH₃ | —(CH₂)₆— |
| 8-24 | —CH₃ | —CH₂CH₂— |
| 8-25 | —CH₃ | —CH₂CH₂OCH₂CH₂— |
| 8-26 | —CH₃ | —(CH₂CH₂O)₃CH₂CH₂— |
| 8-27 | —CH₃ | —(CH₂CH₂O)₈CH₂CH₂— |
| 8-28 | —CH₃ | —(CH₂CH₂O)₁₂CH₂CH₂— |

The compound represented by formula (8) is preferably a compound represented by formula (8′).

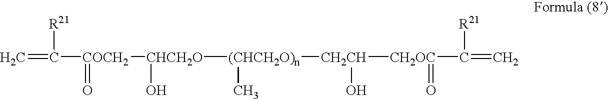

wherein R²¹ represents the same as those denoted above in R²¹ of formula (8); and n represents an integer of from 2 to 15.

Examples of the compound represented by formula (8′) are listed below.

| | R²¹ | n |
|---|---|---|
| 8-29 | —H | 2 |
| 8-30 | —H | ≈3 |
| 8-31 | —H | ≈11 |
| 8-32 | —CH₃ | 2 |
| 8-33 | —CH₃ | ≈3 |
| 8-34 | —CH₃ | ≈11 |

The polymerizable compound content of the light sensitive layer is preferably not more than 70% by weight, and more preferably from 20 to 60% by weight.

### (Spectral Sensitizer)

The light sensitive layer in the invention contains a spectral sensitizer, and the spectral sensitizer is preferably one having absorption maximum in the wavelength regions of from 350 to 450 nm.

Examples of the spectral sensitizer include cyanine, merocyanine, porphyrin, a spiro compound, ferrocene, fluorene, fulgide, imidazole, perylene, phenazine, phenothiazine, acridine, an azo compound, diphenylmethane, triphenylmethane, triphenylamine, coumarin derivatives, ketocumarin, quinacridone, indigo, styryl, pyrylium compounds, pyrromethene compounds, pyrazolotriazole compounds, benzothiazole compounds, barbituric acid derivatives, thiobarbituric acid derivatives, and ketoalcohol borate complexes.

Examples of the coumarin derivative described above include coumarin derivatives B-1 through B-22 disclosed in Japanese Patent O.P.I. Publication No. 8-129258, coumarin derivatives D-1 through D-32 disclosed in Japanese Patent O.P.I. Publication No. 2003-12901, coumarin derivatives 1 through 21 disclosed in Japanese Patent O.P.I. Publication No. 2002-363206, coumarin derivatives 1 through 40 disclosed in Japanese Patent O.P.I. Publication No. 2002-363207, coumarin derivatives 1 through 34 disclosed in Japanese Patent O.P.I. Publication No. 2002-363208, and coumarin derivatives 1 through 56 disclosed in Japanese Patent O.P.I. Publication No. 2002-363209.

As other preferred spectral sensitizers, there are spectral sensitizers disclosed in Japanese Patent O.P.I. Publication Nos. 2000-98605, 2000-147763, 2000-206690, 2000-258910, 2000-309724, 2001-042524, 2002-202598 and 2000-221790.

The content ratio by mole of the spectral sensitizer to the polymerization initiator in the light sensitive layer is preferably from 1:100 to 100:1.

### (Polymeric Binder)

The polymeric binder in the invention is a binder capable of carrying components contained in the light sensitive layer on a support. As the polymeric binder in the invention can be used a polyacrylate resin, a polyvinylbutyral resin, a polyurethane resin, a polyamide resin, a polyester resin, an epoxy resin, a phenol resin, a polycarbonate resin, a polyvinyl butyral resin, a polyvinyl formal resin, a shellac resin, or another natural resin. These resins can be used as an admixture of two or more thereof.

The polymeric binder in the invention is preferably a vinyl copolymer obtained by copolymerization of an acryl monomer, and more preferably a copolymer containing, as the copolymerization component, (a) a carboxyl group-containing monomer unit and (b) an alkyl methacrylate or alkyl acrylate unit.

Examples of the carboxyl group-containing monomer include an α,β-unsaturated carboxylic acid, for example, acrylic acid, methacrylic acid, maleic acid, maleic anhydride, itaconic acid, itaconic anhydride or a carboxylic acid such as a half ester of phthalic acid with 2-hydroxymethacrylic acid.

Examples of the alkyl methacrylate or alkyl acrylate include an unsubstituted alkyl ester such as methylmethacrylate, ethylmethacrylate, propylmethacrylate, butylmethacrylate, amylmethacrylate, hexylmethacrylate, heptylmethacrylate, octylmethacrylate, nonylmethacrylate, decylmethacrylate, undecylmethacrylate, dodecylmethacrylate, methylacrylate, ethylacrylate, propylacrylate, butylacrylate, amylacrylate, hexylacrylate, heptylacrylate, octylacrylate, nonylacrylate, decylacrylate, undecylacrylate, or dodecylacrylate; a cyclic alkyl ester such as cyclohexyl methacrylate or cyclohexyl acrylate; and a substituted alkyl ester such as benzyl methacrylate, 2-chloroethyl methacrylate, N,N-dimethylaminoethyl methacrylate, glycidyl methacrylate, benzyl acrylate, 2-chloroethyl acrylate, N,N-dimethylaminoethyl acrylate or glycidyl acrylate.

The polymeric binder in the invention can further contain, as another monomer unit, a monomer unit derived from the monomer described in the following items (1) through (14):

1) A monomer having an aromatic hydroxy group, for example, o-, (p- or m-) hydroxystyrene, or o-, (p- or m-) hydroxyphenylacrylate;

2) A monomer having an aliphatic hydroxy group, for example, 2-hydroxyethyl acrylate, 2-hydroxyethyl methacrylate, N-methylolacrylamide, N-methylolmethacrylamide, 4-hydroxybutyl acrylate, 4-hydroxybutyl methacrylate, 5-hydroxypentyl acrylate, 5-hydroxypentyl methacrylate, 6-hydroxyhexyl acrylate, 6-hydroxyhexyl methacrylate, N-(2-hydroxyethyl)acrylamide, N-(2-hydroxyethyl)methacrylamide, or hydroxyethyl vinyl ether;

3) A monomer having an aminosulfonyl group, for example, m- or p-aminosulfonylphenyl methacrylate, m- or p-aminosulfonylphenyl acrylate, N-(p-aminosulfonylphenyl)methacrylamide, or N-(p-aminosulfonylphenyl)acrylamide;

4) A monomer having a sulfonamido group, for example, N-(p-toluenesulfonyl)acrylamide, or N-(p-toluenesulfonyl)-methacrylamide;

5) An acrylamide or methacrylamide, for example, acrylamide, methacrylamide, N-ethylacrylamide, N-hexylacrylamide, N-cyclohexylacrylamide, N-phenylacrylamide, N-nitrophenylacrylamide, N-ethyl-N-phenylacrylamide, N-4-hydroxyphenylacrylamide, or N-4-hydroxyphenylmethacrylamide;

6) A monomer having a fluorinated alkyl group, for example, trifluoromethyl acrylate, trifluoromethyl methacrylate, tetrafluoropropyl methacrylate, hexafluoropropyl methacrylate, octafluoropentyl acrylate, octafluoropentyl methacrylate, heptadecafluorodecyl methacrylate, heptadecafluorodecyl methacrylate, or N-butyl-N-(2-acryloxyethyl)heptadecafluorooctylsulfonamide;

7) A vinyl ether, for example, ethyl vinyl ether, 2-chloroethyl vinyl ether, propyl vinyl ether, butyl vinyl ether, octyl vinyl ether, or phenyl vinyl ether;

8) A vinyl ester, for example, vinyl acetate, vinyl chroloacetate, vinyl butyrate, or vinyl benzoate;

9) A styrene, for example, styrene, methylstyrene, or chloromethystyrene;

10) A vinyl ketone, for example, methyl vinyl ketone, ethyl vinyl ketone, propyl vinyl ketone, or phenyl vinyl ketone;

11) An olefin, for example, ethylene, propylene, isobutylene, butadiene, or isoprene;

12) N-vinylpyrrolidone, N-vinylcarbazole, or N-vinylpyridine,

13) A monomer having a cyano group, for example, acrylonitrile, methacrylonitrile, 2-pentenenitrile, 2-methyl-3-butene nitrile, 2-cyanoethyl acrylate, or o-, m- or p-cyanostyrene;

14) A monomer having an amino group, for example, N,N-diethylaminoethyl methacrylate, N,N-dimethylaminoethyl acrylate, N,N-dimethylaminoethyl methacrylate, polybutadiene urethane acrylate, N,N-dimethylaminopropyl acrylamide, N,N-dimethylacrylamide, acryloylmorpholine, N-isopropylacrylamide, or N,N-diethylacrylamide.

Further another monomer may be copolymerized with the above monomer.

The polymeric binder in the invention is preferably a vinyl polymer having in the side chain a carboxyl group and a polymerizable double bond. As the polymer binder is also preferred an unsaturated bond-containing copolymer which is obtained by reacting a carboxyl group contained in the above vinyl copolymer molecule with for example, a compound having a (meth)acryloyl group and an epoxy group.

Examples of the compound having a (meth)acryloyl group and an epoxy group in the molecule include glycidyl acrylate, glycidyl methacrylate and an epoxy group-containing unsaturated compound disclosed in Japanese Patent O.P.I. Publication No. 11-27196. Further, an unsaturated bond-containing copolymer which is obtained by reacting a hydroxyl group contained in the above vinyl copolymer molecule with for example, a compound having a (meth)acryloyl group and an isocyanate group. Examples of the compound having a (meth)acryloyl group and an isocyanate group in the molecule include vinyl isocyanate, (meth)acryl isocyanate, 2-(meth)acroyloxyethyl isocyanate, m- or p-isopropenyl-α,α′-dimethylbenzyl isocyanate, and (meth)acryl isocyanate, or 2-(meth)acroyloxyethyl isocyanate is preferred.

The content of the vinyl polymer having in the side chain a carboxyl group and a polymerizable double bond is preferably from 50 to 100% by weight, and more preferably 100% by weight, based on the total weight of the polymer binder used.

It is preferred in solving the problems raised previously that the light sensitive layer contains a homopolymer or copolymer of N-vinyl pyrrolidone.

The comonomer contained in the N-vinyl pyrrolidone copolymer is not specifically limited, but the comonomer is preferably vinyl acetate.

The polymeric binder content of the light sensitive layer is preferably from 10 to 90% by weight, more preferably from 15 to 70% by weight, and still more preferably from 20 to 50% by weight, in view of sensitivity.

### (Various Additives)

The light sensitive layer in the invention is preferably added with a polymerization inhibitor, in order to prevent undesired polymerization of the ethylenically unsaturated compound during the manufacture or after storage of light sensitive planographic printing plate material.

Examples of the polymerization inhibitor include hydroquinone, p-methoxyphenol, di-t-butyl-p-cresol, pyrrogallol, t-butylcatechol, benzoquinone, 4,4′-thiobis(3-methyl-6-t-butylphenol), 2,2′-methylenebis (4-methyl-6-t-butylphenol), N-nitrosophenylhydroxylamine cerous salt, and 2-t-butyl-6-(3-t-butyl-6-hydroxy-5-mrthylbenzyl)-4-methylphenyl acrylate.

The polymerization inhibitor content is preferably 0.01 to 5% by weight based on the total solid content of the light sensitive layer. Further, in order to prevent undesired polymerization induced by oxygen, behenic acid or a higher fatty acid derivative such as behenic amide may be added to the layer. After the light sensitive layer is coated layer, the coated layer may be dried so that the higher fatty acid derivative is localized at the vicinity of the surface of the light sensitive layer. The content of the higher fatty acid derivative is preferably 0.5 to 10% by weight, based on the total solid content of the light sensitive layer.

A colorant can be also used. As the colorant can be used known materials including commercially available materials. Examples of the colorant include those described in revised edition “Ganryo Binran”, edited by Nippon Ganryo Gijutu Kyoukai (published by Seibunndou Sinkosha), or “Color Index Binran”. Pigment is preferred.

Kinds of the pigment include black pigment, yellow pigment, red pigment, brown pigment, violet pigment, blue pigment, green pigment, fluorescent pigment, and metal powder pigment. Examples of the pigment include inorganic pigment (such as titanium dioxide, carbon black, graphite, zinc oxide, Prussian blue, cadmium sulfide, iron oxide, or chromate of lead, zinc, barium or calcium); and organic pigment (such as azo pigment, thioindigo pigment, anthraquinone pigment, anthanthrone pigment, triphenedioxazine pigment, vat dye pigment, phthalocyanine pigment or its derivative, or quinacridone pigment).

Among these pigment, pigment is preferably used which does not substantially have absorption in the absorption wavelength regions of a spectral sensitizing dye used according to a laser for exposure. The absorption of the pigment used is not more than 0.05, obtained from the reflection spectrum of the pigment measured employing an integrating sphere and employing light with the wavelength of the laser used. The pigment content is preferably 0.1 to 10% by weight, and more preferably 0.2 to 5% by weight, based on the total solid content of the photopolymerizable light sensitive layer composition.

A purple pigment or a blue pigment is preferably utilized in view of absorption of light with the aforesaid photosensitive wavelength region and image visibility after development. Such pigments include, for example, Cobalt Blue, cerulean blue, Alkali Blue, Phonatone Blue 6G, Victoria Blue Lake, metal-free Phthalocyanine Blue, Phthalocyanine Fast Sky Blue, Indathrene Blue, indigo, Dioxane Violet, Isoviolanthrone Violet, Indanthrone Blue and Indanthrone BC. Among them, more preferable are Phthalocyanine Blue and Dioxane Violet.

The light sensitive layer can contain surfactants as a coating improving agent as long as the performance of the invention is not jeopardized. Among these surfactants, a fluorine-contained surfactant is preferred.

Further, in order to improve physical properties of the cured light sensitive layer, the layer can contain an inorganic filler or a plasticizer such as dioctyl phthalate, dimethyl phthalate or tricresyl phosphate. The content of such a material is preferably not more than 10% by weight, based on the total solid content of the light sensitive layer.

The light sensitive planographic printing plate material in the invention is manufactured by preparing a light sensitive layer coating liquid containing the above-described components and then coating on a support the light sensitive layer coating liquid to form a light sensitive layer on the support.

The solvents used in the preparation of the light sensitive layer coating liquid include an alcohol such as sec-butanol, isobutanol, n-hexanol, or benzyl alcohol; a polyhydric alcohol such as diethylene glycol, triethylene glycol, tetraethylene glycol, or 1,5-pentanediol; an ether such as propylene glycol monobutyl ether, dipropylene glycol monomethyl ether, or tripropylene glycol monomethyl ether; a ketone or aldehyde such as diacetone alcohol, cyclohexanone, or methyl cyclohexanone; and an ester such as ethyl lactate, butyl lactate, diethyl oxalate, or methyl benzoate.

The coating amount of the light sensitive layer on a support is preferably from 0.1 to 10 g/m², and more preferably from 0.5 to 5 g/m².

### (Oxygen Shielding Layer)

An oxygen shielding layer or an oxygen shielding layer having anther protective function is optionally provided on the light sensitive layer.

It is preferred that the oxygen shielding layer is highly soluble in a developer as described later. The oxygen shielding contains preferably polyvinyl. Polyvinyl alcohol has the effect of preventing oxygen from transmitting. It is preferred-that polyvinyl pyrrolidone is used in combination which has the effect of increasing-adhesion between the oxygen shielding layer and the light sensitive layer.

Besides the above two polymers, the oxygen shielding layer may contain a water soluble polymer such as polysaccharide, polyethylene glycol, gelatin, glue, casein, hydroxyethyl cellulose, carboxymethyl cellulose, methyl cellulose, hydroxyethyl starch, gum arabic, sucrose octacetate, ammonium alginate, sodium alginate, polyvinyl amine, polyethylene oxide, polystyrene sulfonic acid, polyacrylic acid, or a water soluble polyamide.

In the planographic printing plate material in the invention, adhesive strength between the protective layer and the light sensitive layer is preferably not less than 35 mN/mm, more preferably not less than 50 mN/mm, and still more preferably not less than 75 mN/mm. Preferred composition of the protective layer is disclosed in Japanese Patent O.P.I. Publication No. 10-10742.

The adhesive strength can be determined according to the following method. The adhesive tape with a sufficient adhesive force is applied on the protective layer, and then peeled together with the protective layer under the applied tape in the normal direction relative to the protective layer surface. Force necessary to peel the tape together with the protective layer is defined as adhesive strength.

The protective layer may further contain a surfactant or a matting agent. The protective layer is formed, coating on the photopolymerizable light sensitive layer a coating solution in which the above protective layer composition is dissolved in an appropriate coating solvent, and drying. The main solvent of the coating solution is preferably water or an alcohol solvent such as methanol, ethanol, or iso-propanol.

The coating amount of the protective layer is preferably 0.1 to 5.0 g/m², and more preferably 0.5 to 3.0 g/m².

### (Support)

The support used in the invention is a plate or a sheet capable of carrying the light sensitive layer and preferably has a hydrophilic surface on the side on which the light sensitive layer is to be provided.

As the supports used in the invention, a plate of a metal such as aluminum, stainless steel, chromium or nickel, or a plastic film such as a polyester film, a polyethylene film or a polypropylene film, which is deposited or laminated with the above-described metal can be used. Further, a polyester film, a polyvinyl chloride film or a nylon film whose surface is subjected to hydrophilization treatment can be used. Among the above, the aluminum plate is preferably used, and may be a pure aluminum plate or an aluminum alloy plate.

As the aluminum alloy, there can be used various ones including an alloy of aluminum and a metal such as silicon, copper, manganese, magnesium, chromium, zinc, lead, bismuth, nickel, titanium, sodium or iron. In the aluminum plate for the support, the surface is roughened for water retention.

It is preferable that the aluminum plate is subjected to degreasing treatment for removing rolling oil prior to surface roughening (graining). The degreasing treatments include degreasing treatment employing solvents such as trichlene and thinner, and an emulsion degreasing treatment employing an emulsion such as kerosene or triethanol. It is also possible to use an aqueous alkali solution such as caustic soda for the degreasing treatment. When an aqueous alkali solution such as caustic soda is used for the degreasing treatment, it is possible to remove soils and an oxidized film which can not be removed by the above-mentioned degreasing treatment alone. When an aqueous alkali solution such as caustic soda is used for the degreasing treatment, the resulting support is preferably subjected to desmut treatment in an aqueous solution of an acid such as phosphoric acid, nitric acid, sulfuric acid, chromic acid, or a mixture thereof, since smut is produced on the surface of the support. The surface roughening methods include a mechanical surface roughening method and an electrolytic surface roughening method electrolytically etching the support surface.

Though there is no restriction for the mechanical surface roughening method, a brushing roughening method and a honing roughening method are preferable.

Though there is no restriction for the electrolytic surface roughening method, a method, in which the support is electrolytically surface roughened in an acidic electrolytic solution, is preferred.

After the support has been electrolytically surface roughened, it is preferably dipped in an acid or an aqueous alkali solution in order to remove aluminum dust, etc. produced in the surface of the support. Examples of the acid include sulfuric acid, persulfuric acid, hydrofluoric acid, phosphoric acid, nitric acid and hydrochloric acid, and examples of the alkali include sodium hydroxide and potassium hydroxide. Among those mentioned above, the aqueous alkali solution is preferably used.

The dissolution amount of aluminum in the support surface is preferably 0.5 to 5 g/m². After the support has been dipped in the aqueous alkali solution, it is preferable for the support to be dipped in an acid such as phosphoric acid, nitric acid, sulfuric acid and chromic acid, or in a mixed acid thereof, for neutralization.

The mechanical surface roughening and electrolytic surface roughening may be carried out singly, and the mechanical surface roughening followed by the electrolytic surface roughening may be carried out.

After the surface roughening, anodizing treatment may be carried out. There is no restriction in particular for the method of anodizing treatment used in the invention, and known methods can be used. The anodizing treatment forms an anodization film on the surface of the support.

The support which has been subjected to anodizing treatment is optionally subjected to sealing treatment. For the sealing treatment, it is possible to use known methods using hot water, boiling water, steam, a sodium silicate solution, an aqueous dichromate solution, a nitrite solution and an ammonium acetate solution.

After the above treatment, the support is suitably undercoated with a water soluble resin such as polyvinyl phosphonic acid, a polymer or copolymer having a sulfonic acid in the side chain, or polyacrylic acid; a water soluble metal salt such as zinc borate; a yellow dye; an amine salt; and so on, for hydrophilization treatment. The sol-gel treatment support disclosed in Japanese Patent O.P.I. Publication No. 5-304358, which has a functional group capable of causing addition reaction by radicals as a covalent bond, is suitably used.

### (Coating)

In the invention, the light sensitive layer coating liquid is coated on a support according to a conventional coating method, and dried to form a light sensitive layer on the support. Thus, a light sensitive planographic printing plate material is obtained.

Examples of the coating method include an air doctor coating method, a blade coating method, a wire bar coating method, a knife coating method, a dip coating method, a reverse roll coating method, a gravure coating method, a cast coating method, a curtain coating method, and an extrusion coating method.

A drying temperature of the coated light sensitive layer is preferably from 60 to 160° C., more preferably from 80 to 140° C., and still more preferably from 90 to 120° C.

The oxygen shielding layer is formed in the same manner as the light sensitive layer.

### (Imagewise Exposure)

As a light source for recording an image on the light sensitive planographic printing plate material in the invention, a laser with an emission wavelength of from 350 to 450 nm is preferably used.

Examples of light sources for imagewise exposure of the light sensitive planographic printing plate material include a He—Cd laser (441 nm), a combination of Cr:LiSAF and SHG crystals (430 nm) as a solid laser, and KnbO3, ring resonator (430 nm), AlGaInN (350-350 nm) or AlGaInN semiconductor laser (InGaN type semiconductor laser available on the market, 400-410 nm) as a semiconductor type laser.

When a laser is used for exposure, which can be condensed in the beam form, scanning exposure according to an image can be carried out, and direct writing is possible without using any mask material. When the laser is employed for imagewise exposure, a highly dissolved image can be obtained, since it is easy to condense its exposure spot in minute size.

As a laser scanning method by means of a laser beam, there are a method of scanning on an outer surface of a cylinder, a method of scanning on an inner surface of a cylinder and a method of scanning on a plane. In the method of scanning on an outer surface of a cylinder, laser beam exposure is conducted while a drum around which a recording material is wound is rotated, in which main scanning is represented by the rotation of the drum, while sub-scanning is represented by the movement of the laser beam. In the method of scanning on an inner surface of a cylinder, a recording material is fixed on the inner surface of a drum, a laser beam is emitted from the inside, and main scanning is carried out in the circumferential direction by rotating a part of or an entire part of an optical system, while sub-scanning is carried out in the axial direction by moving straight a part of or an entire part of the optical system in parallel with a shaft of the drum. In the method of scanning on a plane, main scanning by means of a laser beam is carried out through a combination of a polygon mirror, a galvano mirror and an Fθ lens, and sub-scanning is carried out by moving a recording medium. The method of scanning on an outer surface of a cylinder and the method of scanning on an inner surface of a cylinder are suitable for high density image recording, since it is easier to increase accuracy of an optical system.

In the invention, imagewise exposure is carried out at a plate surface energy (an exposure energy at the surface of the planographic printing plate material) of from 10 to 500 mJ/cm², and more preferably from 10 to 300 mJ/cm². This exposure energy can be measured, employing a laser power meter PDGDO-3W produced by Ophir Optronics Inc.

### (Automatic Developing Machine)

It is advantageous that an automatic developing machine is used in order to develop an exposed planographic printing plate material with a developer of the invention to remove a light sensitive layer at non-image portions. The automatic developing machine is preferably provided with a heating device for heating an exposed light sensitive planographic printing plate material upstream a device for removing unexposed portions thereof. Examples of the heating device include a heater employing radiation heat such as a ceramic heater, and a heater employing hot air obtained by heating air by a ceramic heater, and the like. A heater is preferred which can adjust the planographic printing plate material surface temperature to from 80 to 160° C. The automatic developing machine may be equipped with a pre-washing section for removing an oxygen shielding layer and a part of a light sensitive layer of a heated light sensitive planographic printing plate material. The pre-washing section is one with a nozzle for supplying washing water onto a heated light sensitive planographic printing plate material surface or a washing tank in which the plate is immersed. Further, the pre-washing section preferably has a roller-type brush for rubbing a light sensitive planographic printing plate material surface.

In a process for removing unexposed portions of a light sensitive planographic printing plate material employing the developer of the invention, a developing bath of an automatic developing machine can be used which is used for development of a conventional light sensitive planographic printing plate material. It is preferred that the developing bath has a member for adjusting temperature of the developer to a specific temperature, preferably from 20 to 35° C. It is preferred that the automatic developing machine is equipped with a means for automatically introducing the developer in a necessary amount into the developing bath, and a means for discharging an excess of the developer. It is preferred that the automatic developing machine comprises a means for detecting a planographic printing plate material to be transported, a means for calculating the area to be processed of the planographic printing plate material based on the detection, or a means for controlling a replenishing amount of a replenisher to be replenished or replenish timing based on the detection and calculation. It is also preferred that the automatic developing machine comprises a means for controlling a temperature of the developer, a means for detecting a pH and/or electric conductivity of the developer, or a means for controlling a replenishing amount of a replenisher to be replenished, a replenishing amount of water to be replenished and/or the replenishing timing based on the detected pH and/or electric conductivity.

### EXAMPLES

Next, the present invention will be explained employing the following examples, but is not limited thereto. In the examples, “parts” is parts by weight, and “%” is % by weight, unless otherwise specified.

### Example 1

### (Preparation of Support)

A 0.30 mm thick and 1030 mm wide aluminum plate (material JIS A 1050) was successively treated according to the following procedures:

(a) The aluminum plate was subjected to etching treatment, in which the aluminum plate was sprayed with a 70° C. solution having a caustic soda concentration of 2.6 weight % and an aluminum ion concentration of 6.5 weights to dissolve the aluminum by 0.3 g/m², and was washed by means of a water spray.

(b) Desmut treatment was performed by spraying the aluminum plate with an aqueous 1% by weight nitric acid solution (containing aluminum ion of 0.5 weight %) at 30° C., followed by washing by a water spray.

(c) The resulting aluminum plate was subjected to continuous electrolytic roughening treatment, utilizing an alternating voltage of 60 Hz, in a 21° C. electrolytic solution containing 1.1% by weight hydrochloric acid, 0.5% by weight of an aluminum ion and 0.5% by weight of acetic acid, and was washed by water spray. The electrolytic roughening treatment was performed employing a sine wave alternating current at a TP (time taken for current to reach from zero to the peak value) of 2 msec, and employing a carbon electrode as a counter electrode, wherein the current density was 50 A/dm² in terms of effective value, and the quantity of electricity supplied was 900 C/dm².

(d) The resulting aluminum plate was desmutted for 10 seconds in an aqueous 20% by weight phosphoric acid solution having an aluminum ion concentration of 0.5 by weight at 60° C., and washed with water spray.

(e) Employing a conventional anodizing treatment apparatus employing a two-step power-supplied electrolysis method (in which a length of each of the first and second electrolysis section is 6 m, the first power supply section is 3 m long, the second power supply section is 3 m long, and a length of each of the first and second power supply electrodes is 2.4 m), anodizing treatment was performed at 38° C. in a solution having a sulfuric acid concentration of 170 g/l (having an aluminum ion concentration of 0.5 weight %) in the electrolysis section. Thereafter, the plate was sprayed with water and washed.

At this time, in the anodizing treatment apparatus, electric current from power source flowed to the first power supply electrode arranged in the first power supply section, then to the aluminum plate through the electrolytic solution to form an oxidized film on the surface of the aluminum plate in the first electrolysis section, and passed through the electrolysis electrode arranged in the first power supply section to return to the power source.

On the other hand, electric current from a power source flowed to the second power supply electrode arranged in the second power supply section, then similarly to the aluminum plate through the electrolytic solution to form an oxidized film on the surface of the aluminum plate in the second electrolysis section. The quantity of electricity supplied from a power source to the first power supply section and the quantity of electricity supplied from a power source to the second power supply section were same, and the power supply electric current density on the oxidized film surface at the second power supply section was approximately 25 A/dm². In the second power supply section, power was supplied from the surface of the oxidized film of 1.35 g/m². The final amount of the oxidized film was 2.7 g/m². The resulting aluminum plate was washed with water, then subjected to hydrophilization treatment in which the plate was immersed in a 85° C. aqueous 0.4% by weight polyvinyl phosphonic acid solution for 30 seconds, washed with water, and dried with an infrared heater. Thus, an aluminum support was obtained.

The aluminum support obtained above had a centerline average surface roughness (Ra) of 0.65 μm.

### (Preparation of Light Sensitive Planographic Printing Plate Material Samples)

The following photopolymerizable light sensitive layer coating solution 1 was coated on the resulting support through a wire bar, and dried at 95° C. for 1.5 minutes to give a light sensitive layer having a dry thickness of 1.5 g/m².

After that, the following oxygen shielding layer coating solution was coated on the photopolymerizable light sensitive layer using a wire bar, and dried at 65° C. for 3 minutes to give an oxygen shielding layer with a dry thickness of 2.0 g/m². Thus, light sensitive planographic printing plate material samples 1 through 8 were prepared.

(Photopolymerizable light sensitive layer coating solution 1)

| | |
|---|---|
| Polymerizable compound | 50.0 parts |
| (Polymerizable monomer as shown in Table 1) | |
| N-Carboxymethylacridone | 4.0 parts |
| Polymerization initiator (as shown in Table 1) | 3.0 parts |
| Co-initiator (as shown in Table 1) | 0.3 parts |
| N-vinyl pyrrolidone-vinyl acetate copolymer | 20.0 parts |
| VA64 (produced by BASF Co., Ltd.) | |
| Poly(N-vinyl pyrrolidone) | 20.0 parts |
| Luvitec K30 (produced by BASF Co., Ltd.) | |
| Acetylene type surfactant | 0.5 parts |
| Surfinol 465, produced by Air Products Co., Ltd.) | |
| Phthalocyanine pigment dispersion | 3.0 parts |
| (MHI 454, produced by Mikuni Shikiso Co., Ltd.) | |
| Water | 450 parts |
| Ethanol | 450 parts |

(Oxygen shielding layer coating solution)

| | |
|---|---|
| Polyvinyl alcohol (GL-05, produced | 90 parts |
| by Nippon Gosei Kagaku Co., Ltd.) | |
| Poly(N-vinyl pyrrolidone) (Luvitec K-30, | 5 parts |
| produced by ISP Japan Co., Ltd.) | |
| Polyethylene imine | 5 parts |
| (Lupasol WF, available from BASF Co., Ltd.) | |
| Surfactant Surfinol (produced by | 0.5 parts |
| Sisshin Kagaku Kogyo Co., Ltd.) | |
| Water | 900 parts |

TABLE 1

| Sample | | Polymerization | Polymerizable |
|---|---|---|---|
| No. | Co-initiator | Initiator | monomer |
| 1 | 3-04 | Compound 2 | 8-1 |
| 2 | 4-01 | Compound 2 | 8-10 |
| 3 | 5-09 | Compound 2 | 8-15 |
| 4 | 6-01 | Compound 2 | 8-29 |
| 5 | 7-02 | Compound 2 | 8-32 |
| 6 | Compound 1 | Compound 2 | 8-1 |
| 7 | 5-01 | Compound 3 | 8-1 |
| 8 | Compound 1 | Compound 3 | 8-12 |

Compound 1

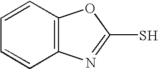

Compound 2

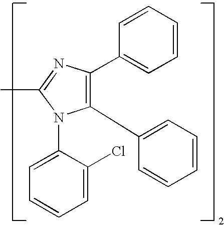

Compound 3

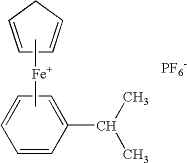

### (Preparation of Planographic Printing Plate Samples 1 Through 28)

Employing a plate setter (modification of TigerCat produced by ECRM Co., Ltd.) installed with a 30 mW light source emitting a 408 nm light, light sensitive planographic printing plate material samples 1 through 8 obtained above were imagewise exposed at a resolving degree of 2400 dpi. (Herein, dpi represents the dot numbers per 2.54 cm, and the image pattern used for the exposure comprised a 100% solid image, and a 50% square dot with a screen line number of 175.

Subsequently, each of the exposed samples was subjected to development treatment, employing an automatic developing machine PHW 32-V produced by Technigraph Co., Ltd. Herein, the automatic developing machine comprised a pre-washing section for removing an oxygen shielding layer before development, a development section comprising a developer tank charged with developer having the composition as shown below, a post-washing section for removing the developer remaining on the developed sample, a gum solution tank charged with a gumming solution (one obtained by diluting GW-3 produced by Mitsubishi Kagaku Co., Ltd.) by a factor of 2 for protecting the surface of the developed material. Thus, planographic printing plate samples 1 through 28 were prepared.

(Developers Having a pH of 2.8: a-1, a-2, a-3, a-4 and a-5)

| | |
|---|---|
| Polyoxyethylene (13) naphthyl ether | 3.0% |
| sulfonic acid sodium salt | |
| Nonionic surfactant (shown in Table 2) | 0.5% |
| Ammonium dihydrogenphosphate | 1.0% |
| Tetrasodium ethylenediaminetetraacetate | 0.5% |
| Water | amount giving 100% in total |

(Developers Having a pH of 5.0: b-1, b-2, b-3, b-4, b-5, b-A and b-B)

| | |
|---|---|
| Polyoxyethylene (13) naphthyl ether | 3.0% |
| sulfonic acid sodium salt | |
| Nonionic surfactant (shown in Table 2) | 0.5% |
| Ammonium dihydrogenphosphate | 0.5% |
| Citric acid | 0.5% |
| Tetrasodium ethylenediaminetetraacetate | 0.5% |
| Water | amount giving 100% in total |

(Developers Having a pH of 8.5: c-1, c-2, c-3, c-4 and c-5)

| | |
|---|---|
| Sodium carbonate | 2.5% |
| Sodium hydrogencarbonate | 0.5% |
| Polyoxyethylene (13) naphthyl ether | 3.0% |
| sulfonic acid sodium salt | |
| Nonionic surfactant (shown in Table 2) | 0.5% |
| Water | amount giving 100% in total |

(Developers Having a pH of 9.5: d-1, d-2, d-3, d-4 or d-5)

| | |
|---|---|
| Sodium carbonate | 2.5% |
| Sodium hydrogencarbonate | 0.5% |
| Polyoxyethylene (13) naphthyl ether | 3.0% |
| sulfonic acid sodium salt | |
| Nonionic surfactant (shown in Table 2) | 0.5% |
| Potassium hydroxide | amount giving a pH of 9.5 |
| Water | amount giving 100% in total |

In Table 2, surfactant A is polyoxyethylene stearyl ether, and surfactant B is polyoxyethylene biphenyl ether.

### <<Evaluation>>

### (Developability)

The planographic printing plate material sample was exposed at minimum exposure amount at which layer thickness reduction was not observed at 100% solid image portions of the developed sample, and developed to obtain a developed sample. Residual layer appeared at the vicinity of the solid image portions was visually observed.

### (Contaminations at Non-Image Portions)

The developed sample was rubbed with a sponge impregnated with PS ink PI-2 (produced by Fuji Film Co., Ltd., and washed with water to provide the PS ink on the image portions. The resulting sample was observed through a loupe, and the number of spot-like contaminations per m² of the non-image portions was counted.

### (Printing Durability)

The light sensitive printing plate material sample was exposed at exposure energy of 200 μJ/cm², and developed to obtain a planographic printing plate sample with an image with a screen number of 175 lines. The resulting planographic printing plate sample was mounted on a press (DAIYA1F-1 produced by Mitsubishi Jukogyo Co., Ltd.), and printing was carried out, wherein a coat paper, printing ink (soybean ink, “Naturalith 100” produced by Dainippon Ink Kagaku Kogyo Co., Ltd.) and dampening water (SG-51, H solution produced by Tokyo Ink Co., Ltd., Concentration: 1.5%) were used. The number of prints printed until dot area reduction at highlight portions of print was observed was evaluated as a measure of printing durability.

The results are shown in Table 2.

TABLE 2

| | Light | | | | | |
|---|---|---|---|---|---|---|
| | sensitive | | | | | |
| Planographic | planographic | | | | | |
| printing | printing | | | | | |
| plate | plate | | Surfactant used | | | |
| sample | material | | | Carbon | | |
| No. | sample No. | Developer | Compound | number | HLB | Remarks |
| 1 | 1 | a-1 | 1-1 | 13 | 13 | Comp. |
| 2 | 1 | b-1 | 1-1 | 13 | 13 | Inv. |
| 3 | 1 | c-1 | 1-1 | 13 | 13 | Inv. |
| 4 | 1 | d-1 | 1-1 | 13 | 13 | Comp. |
| 5 | 1 | a-2 | 1-2 | 9 | 13 | Comp. |
| 6 | 1 | b-2 | 1-2 | 9 | 13 | Inv. |
| 7 | 1 | c-2 | 1-2 | 9 | 13 | Inv. |
| 8 | 1 | d-2 | 1-2 | 9 | 13 | Comp. |
| 9 | 1 | a-3 | 1-3 | 13 | 12 | Comp. |
| 10 | 1 | b-3 | 1-3 | 13 | 12 | Inv. |
| 11 | 1 | c-3 | 1-3 | 13 | 12 | Inv. |
| 12 | 1 | d-3 | 1-3 | 13 | 12 | Comp. |
| 13 | 1 | a-4 | 1-4 | 12 | 14.4 | Comp. |
| 14 | 1 | a-4 | 1-4 | 12 | 14.4 | Inv. |
| 15 | 1 | a-4 | 1-4 | 12 | 14.4 | Inv. |
| 16 | 1 | a-4 | 1-4 | 12 | 14.4 | Comp. |
| 17 | 1 | a-5 | 1-5 | 12 | 12.1 | Comp. |
| 18 | 1 | b-5 | 1-5 | 12 | 12.1 | Inv. |
| 19 | 1 | c-5 | 1-5 | 12 | 12.1 | Inv. |
| 20 | 1 | d-5 | 1-5 | 12 | 12.1 | Comp. |
| 21 | 1 | b-A | A | — | 12.0 | Comp. |
| 22 | 1 | b-B | B | — | 13.0 | Comp. |
| 23 | 3 | b-2 | 1-2 | 9 | 13 | Inv. |
| 24 | 4 | b-2 | 1-2 | 9 | 13 | Inv. |
| 25 | 5 | b-2 | 1-2 | 9 | 13 | Inv. |
| 26 | 6 | b-2 | 1-2 | 9 | 13 | Inv. |
| 27 | 7 | b-2 | 1-2 | 9 | 13 | Inv. |
| 28 | 8 | b-2 | 1-2 | 9 | 13 | Inv. |

| | Light | | | | | |
|---|---|---|---|---|---|---|
| | sensitive | | | | | |
| | planographic | | | | | |
| Planographic | printing | | | | Printing | |
| printing | plate | | | Contaminations | durability | |
| plate | material | | | at non- | (Number of | |
| sample | sample | | Sensitivity | image | sheets | |
| No. | No. | Developability | (μJ/cm²) | portions | printed) | Remarks |
| 1 | 1 | *(i) | 90 | 20 | 22000 | Comp. |
| 2 | 1 | **(ii) | 85 | 2 | 50000 | Inv. |
| 3 | 1 | (ii) | 80 | 0 | 50000 | Inv. |
| 4 | 1 | (ii) | 100 | 0 | 20000 | Comp. |
| 5 | 1 | (i) | 95 | 15 | 20000 | Comp. |
| 6 | 1 | (ii) | 80 | 0 | 47000 | Inv. |
| 7 | 1 | (ii) | 75 | 0 | 50000 | Inv. |
| 8 | 1 | (ii) | 80 | 0 | 20000 | Comp. |
| 9 | 1 | (i) | 95 | 15 | 20000 | Comp. |
| 10 | 1 | (ii) | 85 | 0 | 45000 | Inv. |
| 11 | 1 | (ii) | 80 | 0 | 46000 | Inv. |
| 12 | 1 | (ii) | 100 | 0 | 18000 | Comp. |
| 13 | 1 | (i) | 95 | 20 | 20000 | Comp. |
| 14 | 1 | (ii) | 80 | 0 | 50000 | Inv. |
| 15 | 1 | (ii) | 80 | 0 | 50000 | Inv. |
| 16 | 1 | (ii) | 100 | 0 | 18000 | Comp. |
| 17 | 1 | (i) | 95 | 17 | 22000 | Comp. |
| 18 | 1 | (ii) | 80 | 0 | 50000 | Inv. |
| 19 | 1 | (ii) | 80 | 0 | 50000 | Inv. |
| 20 | 1 | (ii) | 95 | 0 | 17000 | Comp. |
| 21 | 1 | ***(iii) | 95 | 2 | 25000 | Comp. |
| 22 | 1 | (iii) | 100 | 1 | 22000 | Comp. |
| 23 | 3 | (i) | 80 | 0 | 40000 | Inv. |
| 24 | 4 | (i) | 75 | 0 | 45000 | Inv. |
| 25 | 5 | (i) | 77 | 0 | 46000 | Inv. |
| 26 | 6 | (i) | 80 | 0 | 40000 | Inv. |
| 27 | 7 | (i) | 85 | 0 | 38000 | Inv. |
| 28 | 8 | (i) | 80 | 1 | 40000 | Inv. |

Inv.: Inventive,
Comp.: Comparative
*(i): Slight residual layer was observed.
*(ii): No residual layer was observed.
*(iii): Apparent residual layer was observed.

As is apparent from Table 2, the inventive developers high developability and minimize contaminations at non-image portions as compared with the comparative developers, and the planographic printing plates obtained according to the process of the invention provide high printing durability.

### Example 2

Light sensitive planographic printing plate material sample 101 was prepared in the same manner as in light sensitive planographic printing plate material sample 2 of Example 1 above, except that the following photopolymerizable light sensitive layer coating solution 2 was used instead of photopolymerizable light sensitive layer coating solution 1.

(Photopolymerizable light sensitive layer coating solution 2)

| | | |
|---|---|---|
| Polymerizable monomer 1 (described below) | 10.0 | parts |
| NK OLIGO U-4HA (produced by Shin-Nakamura Chemical Co., Ltd.) | | |
| Polymerizable monomer 2 (described below) | 25.0 | parts |
| NK ESTER 4G (produced by Shin-Nakamura Chemical Co., Ltd.) | | |
| Polymerizable monomer 3 (described below) | 25.0 | parts |
| DENAKOL acrylate DA (produced by Nagase Chemtex Corporation) | | |
| Polymerizable monomer 8-10 | 5.0 | parts |
| N-Carboxymethylacridone | 30 | parts |
| Polymerization initiator Compound 2 | 3.0 | parts |
| Co-initiator 7-12 | 0.3 | parts |
| Acetylene type surfactant | 0.5 | parts |
| Surfinol 465, produced by Air Products Co., Ltd.) | | |
| Phthalocyanine pigment dispersion | 3.0 | parts |
| (MHI 454, produced by Mikuni Shikiso Co., Ltd.) | | |
| Water | 450 | parts |
| Ethanol | 450 | parts |

Polymerizable monomer 1

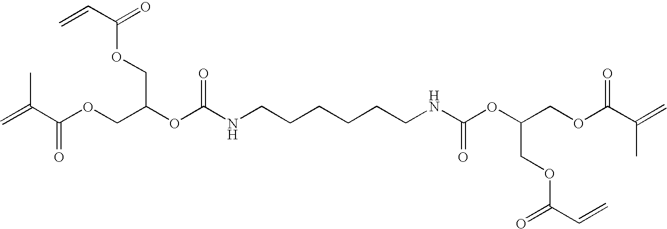

Polymerizable monomer 2

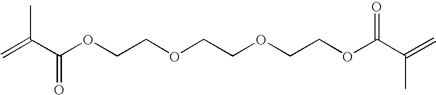

Polymerizable monomer 3

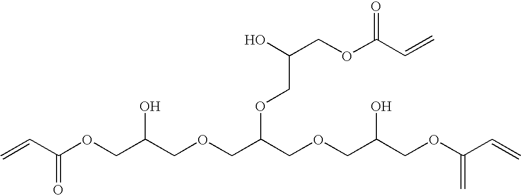

Light sensitive planographic printing plate material sample 101 and light sensitive planographic printing plate material sample 2 were exposed and developed in the same manner as in Example 1, provided that developer as shown in Table 3 was used as a developer. In Table 3, developer a-1, b-1, c-1 and d-1 were added with gum arabic in an amount of 2% as a water soluble resin to obtain developer a-6, b-6, c-6 and d-6, respectively. Thus, planographic printing plate samples 101 and 116 as shown in Table 3 were prepared. The resulting planographic printing plate samples 101 and 116 were evaluated in the same manner as in Example 1. The results are shown in Table 3.

TABLE 3

| | Light | | | | | | | |
|---|---|---|---|---|---|---|---|---|
| | sensitive | | | | | | | |
| | planographic | | | | | | | |
| Planographic | printing | | | | | | Printing | |
| printing | plate | | Water | | Contaminations | | durability | |
| plate | material | | soluble | | at | | (Number | |
| sample | sample | Developer | resin in | | non-image | Sensitivity | of sheets | |
| No. | No. | used | developer | Developability | portions | (μJ/cm²) | printed) | Remarks |
| 101 | 2 | a-1 | None | (i) | 0 | 95 | 20000 | Comp. |
| 102 | 2 | b-1 | None | (ii) | 0 | 80 | 50000 | Inv. |
| 103 | 2 | c-1 | None | (ii) | 0 | 75 | 50000 | Inv. |
| 104 | 2 | d-1 | None | (ii) | 0 | 100 | 30000 | Comp. |
| 105 | 101 | a-1 | None | (i) | 20 | 150 | 15000 | Comp. |
| 106 | 101 | b-1 | None | (ii) | 0 | 120 | 45000 | Inv. |
| 107 | 101 | c-1 | None | (ii) | 0 | 100 | 50000 | Inv. |
| 108 | 101 | d-1 | None | (ii) | 0 | 150 | 20000 | Comp. |
| 109 | 2 | a-6 | Gum arabic | (ii) | 0 | 90 | 20000 | Comp. |
| 110 | 2 | b-6 | Gum arabic | (ii) | 0 | 80 | 50000 | Inv. |
| 111 | 2 | c-6 | Gum arabic | (ii) | 0 | 70 | 50000 | Inv. |
| 112 | 2 | d-6 | Gum arabic | (ii) | 0 | 95 | 25000 | Comp. |
| 113 | 101 | a-6 | Gum arabic | (i) | 10 | 110 | 15000 | Comp. |
| 114 | 101 | b-6 | Gum arabic | (ii) | 0 | 100 | 45000 | Inv. |
| 115 | 101 | c-6 | Gum arabic | (ii) | 0 | 95 | 45000 | Inv. |
| 116 | 101 | d-6 | Gum arabic | (ii) | 7 | 120 | 20000 | Comp. |

Inv.: Inventive,
Comp.: Comparative
*(i): Slight residual layer was observed.
*(ii): No residual layer was observed.

As is apparent form Table 3, the light sensitive planographic printing plate material samples comprising a light sensitive layer containing poly(N-vinyl pyrrolidone) are superior to the light sensitive planographic printing plate material samples comprising a light sensitive layer containing no poly(N-vinyl pyrrolidone). Further, the developer containing a water soluble resin provides preferred results.

What is claimed is:

1. A developer for an imagewise exposed light sensitive planographic printing plate material, wherein the developer is an aqueous solution with a pH at 25° C. of from 3.0 to 9.0 containing a compound represented by formula (1),
R¹-Z-(R²—O)ₙ—H Formula (1)
wherein R¹ represents a substituted or unsubstituted branched alkyl group having a total carbon atom number of not more than 20; R² represents a substituted or unsubstituted alkylene group having a carbon atom number of from 1 to 10; Z represents —O— or —NH—; n represents an integer of 2 to 100, provided that when n is 2 or more, plural R²S may be the same or different.

2. The developer of claim 1, wherein the ratio C₂/C₁ of a carbon number C₂ in the side chain of R¹ to a carbon number C₁ in the main chain of R¹ is from 0.05 to 3.0.

3. The developer of claim 1, wherein in formula (1), the main chain carbon atom number of R¹ is from 3 to 19, and the side chain carbon atom number of R¹ is from 1 to 9.

4. The developer of claim 1, wherein the compound represented by formula (1) has an HLB of from 11 to 15.

5. The developer of claim 1, wherein Z in formula (1) is —NH—.

6. The developer of claim 1, wherein the developer further contains a water soluble resin.

7. A process of manufacturing a planographic printing plate from a planographic printing plate material comprising a support and provided thereon, a light sensitive layer and an oxygen shielding layer in that order, the light sensitive layer containing a spectral sensitizer, a polymerization initiator, a co-initiator, a polymerizable compound and a polymeric binder, and the oxygen shielding layer containing polyvinyl alcohol, the process comprising the steps of:
imagewise exposing the planographic printing plate material; and
developing the exposed planographic printing plate material with the developer of claim 1.

8. The process of claim 7, wherein the polymerization initiator is a hexaarylbiimidazole compound.

9. The process of claim 7, wherein the co-initiator is a compound represented by formula (2), 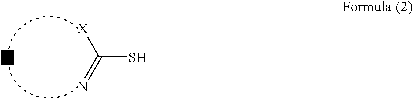
wherein X represents an oxygen atom, a selenium atom or —NR₁—, in which R₁ represents an unsubstituted or substituted alkyl group or an unsubstituted or substituted aryl group; and Y represents an atomic group necessary to form a 5-membered heterocyclic group together with N═C—X.

10. The process of claim 7, wherein the polymerizable compound has a hydroxyl group in the molecule.

11. The process of claim 7, wherein the polymeric binder is a homopolymer or copolymer of N-vinyl pyrrolidone.

12. The process of claim 7, between imagewise exposing and developing steps, further comprising the step of heating the exposed light sensitive planographic printing plate material to 80 to 160° C.

13. The process of claim 12, between heating and developing steps, further comprising the step of removing the oxygen shielding layer and a part of the light sensitive layer by water washing.

14. The process of claim 7, wherein exposing is carried out employing a laser.
